(19) United States
(12) Patent Application Publication
(10) Pub. No.: US 2014/0034115 A1
(43) Pub. Date: Feb. 6, 2014

(54) INSULATING LAYER PROVIDED METAL SUBSTRATE AND MANUFACTURING METHOD OF THE SAME

(71) Applicant: FUJIFILM Corporation, Tokyo (JP)

(72) Inventors: Keigo SATO, Ashigarakami-gun (JP); Youta MIYASHITA, Ashigarakami-gun (JP); Shigenori YUUYA, Ashigarakami-gun (JP)

(73) Assignee: FUJIFILM Corporation, Tokyo (JP)

(21) Appl. No.: 14/046,441

(22) Filed: Oct. 4, 2013

Related U.S. Application Data
(63) Continuation of application No. PCT/JP2012/002355, filed on Apr. 4, 2012.

(30) Foreign Application Priority Data
Apr. 5, 2011 (JP) 2011-083337
Sep. 28, 2011 (JP) 2011-212196
Sep. 28, 2011 (JP) 2011-212199
Feb. 29, 2012 (JP) 2012-042931

(51) Int. Cl. H01L 31/02

(52) U.S. Cl. CPC H01L 31/02008
USPC 136/252; 428/610; 428/635; 427/372.2; 205/224

(57) ABSTRACT

An insulating layer provided metal substrate, including a metal substrate having a metallic aluminum on at least one surface and a composite structure layer formed of a porous aluminum oxide film provided on the metallic aluminum by anodization and an alkali metal silicate film covering pore surfaces of the porous aluminum oxide film, in which the mass ratio of silicon to aluminum in the composite structure layer is 0.001 to 0.2 at an arbitrary position within a region between a position 1 μm to the composite structure layer side in thickness from the interface between the composite structure layer and the metallic aluminum and a position 1 μm to the composite structure layer side in thickness from the interface between the composite structure layer and an upper layer on the opposite side of the metallic aluminum.

### TECHNICAL FIELD

The present invention relates to an insulating layer provided metal substrate and a manufacturing method of the same. The invention also relates to a semiconductor apparatus using the insulating layer provided metal substrate.

### BACKGROUND ART

Photoelectric conversion devices having, on a substrate, a layer structure of a lower electrode (back contact electrode), a photoelectric conversion layer that absorbs light to generate electric current, and an upper electrode (transparent electrode) are used for solar cell applications and the like. Most of the conventional solar cells are Si-based cells that use bulk monocrystalline Si, polycrystalline Si, or thin film amorphous Si. Recently, however, research and development of compound semiconductor-based solar cells that do not depend on Si has been carried out. As compound semiconductor solar cells, thin film systems, such as CIS (Cu—In—Se) systems formed of group Ib element, group TIM element, and group VIb element, CIGS (Cu—In—Ga—Se) systems, and the like are known to have high optical absorption and high photoelectric conversion efficiency.

In CIS or CIGS photoelectric conversion devices, it is known that diffusion of an alkali metal, preferably Na, into the photoelectric conversion layer may improve the crystallization of the photoelectric conversion layer and photoelectric conversion efficiency. Conventionally, the diffusion of Na into photoelectric conversion layer has been effected using a soda-lime glass substrate that includes Na.

The use of a metal substrate as a solar cell substrate, however, poses a problem that the conversion efficiency is not improved as sodium is not supplied from the substrate. Consequently, in the case where a substrate that does not include sodium is used, one of the following is performed: providing an alkali supply layer by liquid phase method; introducing sodium by co-deposition with CIGS, or providing Mo—Na as the electrode. For example, U.S. Patent Application Publication No. 20080257404 discloses that alkali is doped in an aluminum oxide insulating layer. Such alkali doping in an aluminum oxide insulating layer, however, poses a problem of low crack resistance and low adequacy of flexibility.

Japanese Unexamined Patent Publication No. 2009-267332 discloses that an alkali metal silicate, more specifically, a sodium silicate is coated by a liquid phase method. For aluminum substrates, in general, it is possible to obtain a high adhesion insulating coating without any pinhole by forming an anodized aluminum oxide film (Japanese Unexamined Patent Publication No. 2000-349320). Further, the porous structure of the anodized aluminum oxide film is a structure that spreads the stress and excels in crack resistance against the dense alumina film. Japanese Unexamined Patent Publication No. 2010-232427 discloses that sodium is doped in such an anodized aluminum oxide film by bringing the film into contact with a sodium hydroxide aqueous solution.

### DISCLOSURE OF THE INVENTION

The method in which an alkali metal is doped in an anodized aluminum oxide film as described in Japanese Unexamined Patent Publication No. 2010-232427, however, poses a problem that a sufficient amount of alkali may not be secured since alkali is present only on the outermost surface of the pore walls or adjacent to the surface of internal pore walls. In the method in which an alkali metal is doped in an anodized aluminum oxide film by brining the film into contact with a solution containing a water soluble compound, however, the alkali metal is eluted by the process in which the film is immersed in water, as in the case in which washing is performed subsequent to Mo film forming and scribing or a photoelectric conversion layer is formed by a liquid phase method and alkali metal is diffused by the subsequent annealing so that the doped precious alkali metal is wasted away and power generation efficiency cannot be improved.

In the mean time, in the method in which an alkali supply layer is provided on an anodized aluminum oxide film by a liquid phase method as described in Japanese Unexamined Patent Publication No. 2009-267332, diffusion of the alkali to the anodized aluminum oxide film occurs at the same time, thereby resulting, also in this case, in loss of alkali metal. The anodized aluminum oxide film has a very large surface area as it has mesa to micro pores and, although not clear, the possible diffusion path of alkali metal ions is presumed to be the exchange with H⁺ of OH groups on the surface of the film. Further, aluminum oxide is hydrophilic and the anodized aluminum oxide film has meso to micro pores as described above so that it is very likely to absorb moisture. Consequently, a problem arises that, even though the film may provide insulation under dry environment, the insulation is reduced under moisture environment. Still further, the anodized aluminum oxide film is formed on a porous layer, so that it is necessary to take into account the problem of pinholes, adhesion with the upper layer, and the like.

When trying to form a layer of silicon compound on a porous anodized film by coating an alkali metal silicate aqueous solution, the coating liquid is impregnated into the pores of the porous anodized film and a silicon compound layer is formed also inside of the porous anodized film. In this case, if an alkali metal is included in the silicon compound, the alkali metal itself may act as a conductive carrier or moisture is likely to be adsorbed and the conductivity is increased, thereby posing a problem that the function as the insulating layer is degraded and the leakage current is increased.

The present invention has been developed in view of the circumstances described above, and it is an object of the present invention to provide a substrate with an anodized aluminum oxide film, as an insulating layer provided metal substrate, excellent in stress and crack resistance, and capable of efficiently diffusing alkali metal ions to the photoelectric conversion semiconductor layer and improving photoelectric conversion efficiency of the photoelectric conversion device, while reliably securing electrical insulation, and a manufacturing method of the same. It is a further object of the present invention to provide a semiconductor apparatus using the insulating layer provided metal substrate.

The insulating layer provided metal substrate according to a first embodiment of the present invention includes a metal substrate having a metallic aluminum on at least one surface and a composite structure layer formed of a porous aluminum oxide film provided on the metallic aluminum by anodization and an alkali metal silicate film covering the porous aluminum oxide film and pore surfaces of the porous aluminum oxide film,

wherein the mass ratio of silicon to aluminum in the composite structure layer is 0.001 to 0.2 at an arbitrary position within a region between a position 1 μm to the composite structure layer side in thickness from the interface between the composite structure layer and the metallic aluminum and a position 1 μm to the composite structure layer side in thickness from the interface between the composite structure layer and an upper layer on the opposite side of the metallic aluminum.

Preferably, the alkali metal of the alkali metal silicate film includes at least sodium, and the mass ratio of sodium to aluminum in the composite structure layer is 0.001 to 0.1 at an arbitrary position within a region between a position 1 μm to the composite structure layer side in thickness from the interface between the composite structure layer and the metallic aluminum and a position 1 μm to the composite structure layer side in thickness from the interface between the composite structure layer and an upper layer on the opposite side of the metallic aluminum. Preferably, the alkali metal of the alkali metal silicate film includes sodium and lithium or potassium. Preferably, the alkali metal silicate film includes boron or phosphorus. Preferably, the metal substrate includes an alkali metal silicate layer provided on the composite structure layer and covering the porous aluminum oxide film at end faces.

The insulating layer provided metal substrate according to a second embodiment of the present invention includes a metal substrate having a metallic aluminum on at least one surface, a composite structure layer formed of a porous aluminum oxide film provided on the metallic aluminum by anodization and an inorganic metal oxide film covering the surface of the porous aluminum oxide film and pore surfaces of the porous aluminum oxide film, and an alkali metal silicate layer formed on the composite structure layer,

wherein the composite structure layer does not substantially include any alkali metal. Preferably, the inorganic metal oxide of the inorganic metal oxide film is silicon oxide. Preferably, the thickness of the inorganic metal oxide film covering the surface of the porous aluminum oxide film is not greater than 300 nm.

Preferably, the thickness of the alkali metal silicate layer is not greater than 1 μm. Preferably, the metal substrate is a clad material in which an aluminum plate is integrated on one or both surfaces of an aluminum, stainless steel, or steel plate. Preferably, the porous aluminum oxide film has a compressive stress.

A semiconductor apparatus of the present invention includes the insulating layer provided metal substrate of the first or second embodiment and a semiconductor circuit formed on the substrate. Preferably, the metal substrate is connected to a portion of the semiconductor circuit having a higher electric potential than an average electric potential of the semiconductor circuit. More preferably, the metal substrate is short-circuited to a portion of the semiconductor circuit which becomes the highest in electric potential when the semiconductor circuit is activated. Preferably, the semiconductor of the semiconductor circuit is a photoelectric conversion semiconductor.

A method of manufacturing an insulating layer provided metal substrate according a first embodiment of the present invention includes the steps of forming the porous aluminum oxide film on a metallic aluminum provided on at least one surface of a metal substrate by anodizing the metallic aluminum, immersing the porous aluminum oxide film into a 5 mass % to 30 mass % alkali metal silicate aqueous solution or coating a 5 mass % to 30 mass % alkali metal silicate aqueous solution on the porous aluminum oxide film, and performing heat treatment on the metal substrate after the immersion or coating,

thereby forming a composite structure layer formed of the porous aluminum oxide film and an alkali metal silicate film covering the porous aluminum oxide film and pore surfaces of the porous aluminum oxide film.

Preferably, the temperature of the heat treatment is 200° C. to 600° C.

According to the insulating layer provided metal substrate of the first embodiment of the present invention, a composite structure layer is formed by a porous aluminum oxide film and an alkali metal silicate film covering pore surfaces of the porous aluminum oxide film and the mass ratio of silicon to aluminum in the composite structure layer is 0.001 to 0.2 at an arbitrary position within a region between a position 1 μm to the composite structure layer side in thickness from the interface between the composite structure layer and the metallic aluminum and a position 1 μm to the composite structure layer side in thickness from the interface between the composite structure layer and an upper layer on the opposite side of the metallic aluminum. This makes it less likely that alkali diffusion occurs to the porous aluminum oxide film and moisture adsorption to pore surfaces of the porous aluminum oxide film is inhibited when immersed into water in the manufacturing process, so that reduction in insulation under humid environment may be inhibited and elution of alkali metal is suppressed, whereby alkali ions may be diffused efficiently to the photoelectric conversion semiconductor layer.

If the alkali metal of the alkali metal silicate film includes at least sodium and the mass ratio of sodium to aluminum in the composite structure layer is 0.001 to 0.1 at an arbitrary position within a region within a region between a position 1 μm to the composite structure layer side in thickness from the interface between the composite structure layer and the metallic aluminum and a position 1 μm to the composite structure layer side in thickness from the interface between the composite structure layer and an upper layer on the opposite side of the metallic aluminum, sodium included in the composite structure layer is diffused to the photoelectric conversion semiconductor layer, so that the composite structure layer itself has an effect of sodium supply layer and may improve the photoelectric conversion efficiency of the photoelectric conversion device.

If an alkali metal silicate layer is provided on the composite structure layer to cover the porous aluminum oxide film at end faces, pores of the porous aluminum oxide film are covered, so that even in the case where an alkali metal silicate layer is provided on the composite structure layer by coating, no coating liquid is impregnated into the pores of the porous anodized film and function as an insulating layer may be ensured. In addition, a planarity effect may be obtained by the inorganic metal oxide film formed, so that a substrate defect that will lead to degradation of power generation efficiency of the photoelectric conversion device provided on the inorganic metal oxide film may be suppressed and insulation reduction may be suppressed by preventing moisture adsorption.

The insulating layer provided metal substrate of the second embodiment of the present invention includes a metal substrate having a metallic aluminum on at least one surface, a composite structure layer formed of a porous aluminum oxide film provided on the metallic aluminum by anodization and an inorganic metal oxide film covering the surface of the porous aluminum oxide film and pore surfaces of the porous aluminum oxide film, and an alkali metal silicate layer formed on the composite structure layer, and the composite structure layer does not include any alkali metal, so that the alkali metal itself does not act as conductive carrier and the function as the insulating layer may be ensured. Further, as the surface of porous aluminum oxide film and the pore surfaces are covered by the inorganic metal oxide film, moisture is less likely to be adsorbed and the function as an insulating layer may be ensured.

### BRIEF DESCRIPTION OF DRAWINGS

FIG. 1 is a partially enlarged cross-sectional view of one form of the insulating layer provided metal substrate according to a first embodiment of the present invention.

FIG. 2 is a partially enlarged cross-sectional view of another form of the insulating layer provided metal substrate according to the first embodiment of the present invention.

FIG. 3 is a SEM photograph of the form shown in FIG. 2.

FIG. 4 is a partially enlarged cross-sectional view of one form of the insulating layer provided metal substrate according to a second embodiment of the present invention.

FIG. 5 is a schematic cross-sectional view of an embodiment of a photoelectric conversion device using the insulating layer provided metal substrate.

FIG. 6 is a schematic cross-sectional view of an embodiment of the photoelectric conversion apparatus of the present invention

FIG. 7 is a schematic cross-section view of the photoelectric conversion apparatus according to an embodiment of the present invention, illustrating a wiring example.

FIG. 8 is a graph illustrating Si/Al mass ratios of composite structure layers in the series of Example 1.

FIG. 9 is a graph illustrating Na/Al mass ratios of composite structure layers in the series of Example 1.

FIG. 10 is a graph illustrating Si/Al mass ratios of composite structure layers in the series of Example 2.

FIG. 11 is a graph illustrating Na/Al mass ratios of composite structure layers in the series of Example 2.

FIG. 12 is a graph illustrating the relationship between the water immersion time in heat treatment and amounts of Na/Si.

FIG. 13 shows electron microscope photographs of CIGS crystals.

FIG. 14 is a graph illustrating leakage current densities of Example 21 and Comparative Example 21 with respect to the applied voltage.

FIG. 15 is a graph illustrating the applied voltage with respect to the current injection time.

FIG. 16 shows SEM photographs of fracture surfaces of substrates of Examples 31 and 32.

FIG. 17 is a graph illustrating leakage current densities of Examples 31 and 32 with respect to the applied voltage.

### BEST MODE FOR CARRYING OUT THE INVENTION

[Insulating Layer Provided Metal Substrate of First Embodiment]

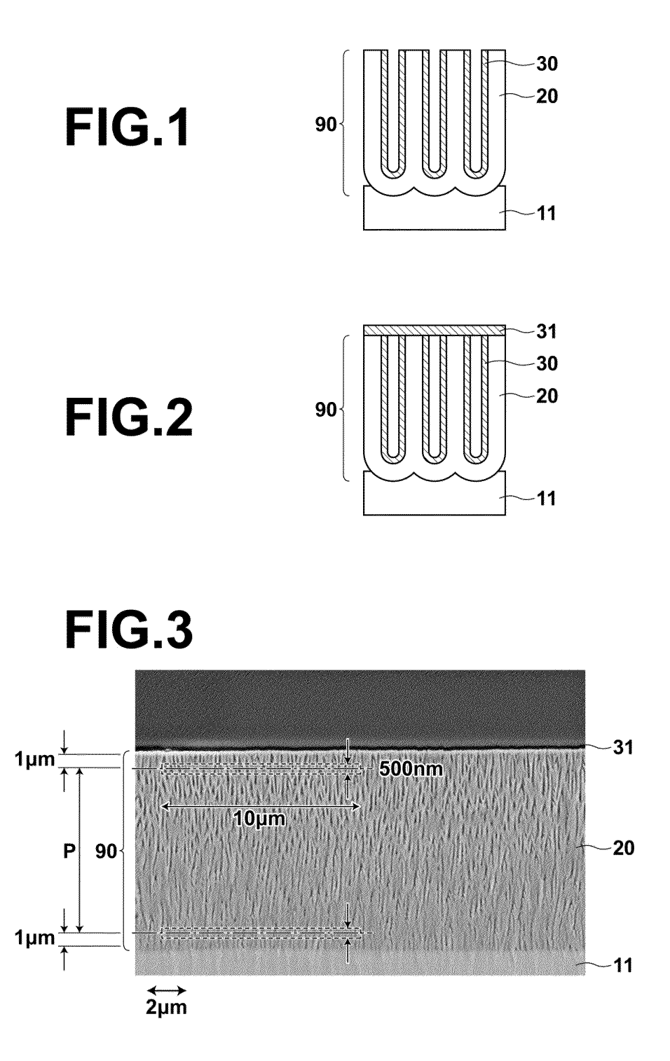

An insulating layer provided metal substrate of first embodiment of the present invention will be described in detail first with reference to the accompanying drawings. Each component in the drawings is not necessarily drawn to scale for ease of visual recognition (hereinafter, the same applies to the other schematic drawings). FIGS. 1 and 2 are partially enlarged cross-sectional views of the insulating layer provided metal substrate of the first embodiment. The insulating layer provided metal substrate of the first embodiment includes a metal substrate having a metallic aluminum 11 on at least one surface and a composite structure layer 90 formed of a porous aluminum oxide film 20 provided on the metallic aluminum 11 by anodization and an alkali metal silicate film 30 covering the porous aluminum oxide film 20 and pore surfaces of the porous aluminum oxide film 20. The thickness of the composite structure layer 90 is preferably 1 to 30 μm, more preferably 3 to 20 μm, and particularly preferably 5 to 15 μm.

The alkali metal silicate film 30 may cover only the inner pore surfaces of the porous aluminum oxide film 20, as illustrated in FIG. 1 or may form an alkali metal silicate layer 31 on the surface of the porous aluminum oxide film 20 as well as covering the inner pore surfaces of the porous aluminum oxide film 20, as illustrated in FIG. 2.

If the alkali metal silicate layer 31 is provided, the thickness thereof is preferable to be not greater than 2 μm, more preferable to be 0.01 to 1 μm, and further preferable to be 0.1 to 1 μm. If the thickness of the alkali metal silicate layer 31 is greater than 2 μm, the alkali metal silicate layer may contract when structured water included in the alkali metal silicate aqueous solution is desorbed at the time of forming the alkali metal silicate layer 31 and a crack or a foam may be generated in the formed alkali metal silicate layer, whereby surface smoothness may possibly be lost. The alkali metal silicate layer is formed by immersing the porous aluminum oxide film 20 in an alkali metal silicate aqueous solution or coating an alkali metal silicate aqueous solution on the porous aluminum oxide film 20 and performing heat treatment. If the alkali metal silicate layer is thick, the porous aluminum oxide film may have a crack due to thermal expansion difference since the alkali metal silicate layer and porous aluminum oxide film have different thermal expansion coefficients, thereby resulting in reduced insulation.

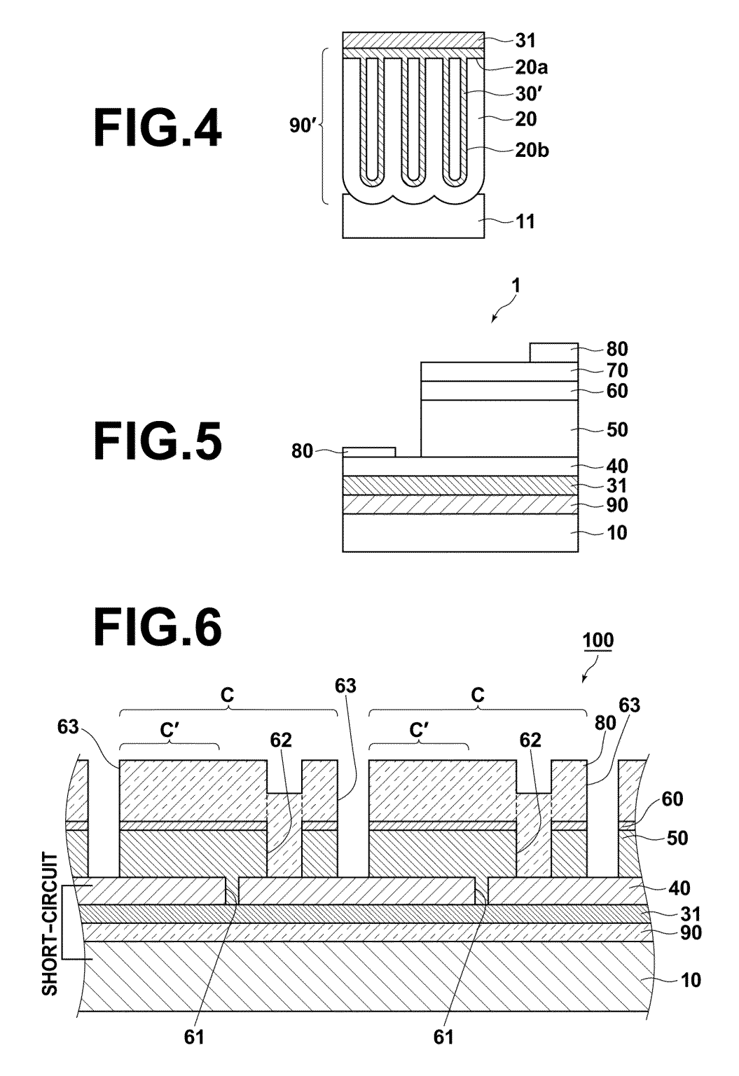

FIG. 3 is a SEM photograph of the insulating layer provided metal substrate in the embodiment shown in FIG. 2. The composite structure layer 90 is formed of the porous aluminum oxide film 20 and alkali metal silicate film 30 (in FIG. 3, the lead line of the alkali metal silicate film 30 is omitted). The mass ratio of silicon to aluminum (Si/Al ratio) in the composite structure layer 90 is in the range of 0.001 to 0.2, preferably in the range of 0.005 to 0.15, and more preferably in the range of 0.005 to 0.1 at an arbitrary position within a region P between a position 1 μm to the composite structure layer 90 side in thickness from the interface between the composite structure layer 90 and metallic aluminum 11 and a position 1 μm to the composite structure layer 90 side in thickness from the interface between the composite structure layer 90 and an upper layer on the opposite side of the metallic aluminum 11 (in FIG. 3, the upper layer is the alkali metal silicate layer 31 and in the case of the insulating layer provided metal substrate without the alkali metal silicate layer 31 in the embodiment illustrated in FIG. 1, the upper layer is a lower electrode 40 shown in FIG. 4, to be described later. The same applies to the description of Na/Al provided hereinafter).

The state in which the Si/Al ratio is less than 0.001 is substantially identical to the state in which no alkali metal silicate is present, so that the diffusion suppression effect of alkali metal to porous aluminum oxide film 20 may not be obtained. Further, elution suppression effect of alkali metal in washing with water is low. The composite structure layer 90 is produced by immersing the porous aluminum oxide film 20 in an aqueous solution of alkali metal silicate, as described later. If the immersion time is long, the pore walls of the porous aluminum oxide film 20 become thin and the strength of the porous aluminum oxide film 20 itself is reduced, leading to cracking, reduced heat resistance, and reduced insulation. A Si/Al ratio greater than 0.2 is undesirable because the pore walls of the porous aluminum oxide film 20 become thin as described above.

If the alkali metal of the alkali metal silicate is sodium (hereinafter, the description will be mainly made of a case in which the alkali metal of the alkali metal silicate is sodium), the mass ratio of sodium to aluminum (Na/Al ratio) in the composite structure layer 90 is preferably in the range of 0.001 to 0.1 and more preferably in the range of 0.005 to 0.05 at an arbitrary position within a region P between a position 1 μm to the composite structure layer 90 side in thickness from the interface between the composite structure layer 90 and metallic aluminum 11 and a position 1 μm to the composite structure layer 90 side in thickness from the interface between the composite structure layer 90 and an upper layer located on the opposite side of the metallic aluminum 11. The state in which the Na/Al ratio is less than 0.001 is substantially identical to the state in which no alkali metal silicate is present, so that the sodium diffusion effect from the composite structure layer to the photoelectric conversion semiconductor layer cannot be obtained. On the other hand, a Na/Al ratio greater than 0.1 is undesirable, because the pore walls of the porous aluminum oxide film 20 become thin, in addition to reduced insulation due to increased hygroscopicity.

Preferably, the alkali metal silicate film includes sodium and the other alkali metal, in particular, sodium with lithium or sodium with potassium. The combined use of sodium with the other alkali metal, in particular, lithium or potassium may provide advantageous effect of improved power generation efficiency. The action mechanism of this is not necessarily clear, but it is presumed that, as lithium and potassium have low hygroscopicity in comparison with sodium, the inclusion of lithium or potassium in the alkali metal silicate layer results in reduced amount of moisture in the alkali metal silicate layer in absolute terms, thereby making oxidation reaction due to water unlikely to occur, so that the generation of impurities is suppressed, in addition to reduced sodium elution in washing with water. Note that even in the case where sodium and the other alkali metal are included, the mass ratio in the composite structure layer 90 is the mass ratio of sodium to aluminum (Na/Al ratio).

The mass ratio of silicon to aluminum (Si/Al ratio) and the mass ratio of sodium to aluminum (Na/Al ratio) are calculated from the values obtained by ion-polishing a cross-sectional surface of the porous aluminum oxide film 20 and performed measurement with a 5 keV SEM-EDX. In the present invention, values obtained by observing a sample with a polished cross-section surface using SEM (ULTRA 55, manufactured by ZEISS) from a direction perpendicular to the cross-sectional surface and performing semi-quantitative analysis on a rectangular region of 500 nm in the depth direction and 10 μm in the surface parallel direction by Non-Standard method (ZAF method) with an accelerating voltage of 5 keV. Various methods are used for composition analysis, but the use of this method allows a general composition distribution in the region several hundred nanometers inside of the porous aluminum oxide film 20 to be obtained easily.

As the region adjacent to the interface between the porous aluminum oxide film 20 and the adjacent layer is likely to be influenced from outside the region, the mass ratios are defined by the region which is the entire cross-section of the porous aluminum oxide film 20 except for a portion 1 μm to the composite structure layer 90 side from the interface between the composite structure layer 90 and the metallic aluminum 11 and a portion 1 μm to the composite structure layer 90 side from the interface between the composite structure layer 90 and an upper layer located on the opposite side of the metallic aluminum 11 in the present invention.

The mass ratio of silicon to aluminum (Si/Al ratio) and the mass ratio of sodium to aluminum (Na/Al ratio) may have a concentration gradient which becomes large toward the upper layer of the composite structure layer 90 and small toward the bottom of the pores of the porous aluminum oxide film 20. Such concentration gradient in the Si/Al ratio will result in that the closer the position to the photoelectric conversion layer, the higher the concentration of alkali metal silicate and diffusion suppression function may be obtained effectively. Further, such concentration gradient in the Na/Al ratio will result in that the closer the position to the photoelectric conversion layer, the higher the concentration of sodium, whereby effective supply of sodium to the photoelectric conversion layer becomes possible.

The reason why the concentration gradient is formed is presumed that the closer to the surface of the porous aluminum oxide film 20, the larger the pore surface area of the porous aluminum oxide film 20 and the greater the amount of sodium silicate on the pore surface. The aluminum oxide film is generally produced with an acidic electrolyte, as described later and for aluminum oxide films produced using the same acid electrolyte, the higher the temperature of the acid electrolyte in anodization, the higher the concentration gradient. This is presumed that the higher the temperature of the acid electrolyte, the stronger the dissolution of the anodized film, and a position closer to the surface of the porous aluminum oxide film exposed to acid electrolyte environment for a longer time has a larger specific surface area.

The insulating layer provided metal substrate of the first embodiment of the present invention may be produced by forming a porous aluminum oxide film on a metallic aluminum provided on at least one surface by anodizing the metallic aluminum, immersing the porous aluminum oxide film in a 5 mass % to 30 mass % alkali metal silicate aqueous solution (hereinafter, simply referred to as the “alkali metal silicate aqueous solution”) or coating an alkali metal silicate aqueous solution on the porous aluminum oxide film, and forming the composite structure layer through heat treatment after the immersion or coating.

Formation of the porous aluminum oxide film will be described first. The metal substrate has a metallic aluminum on at least one surface. In particular, a clad material in which an aluminum plate is integrated on one or both surfaces of an aluminum, stainless steel, or steel plate is preferable from the viewpoint of ease of anodization and high durability. A clad material integrated with aluminum plates on both surfaces is more preferable as the warpage of the substrate due to a difference in thermal expansion coefficient between the aluminum and the oxide film (Al₂O₃) is suppressed, whereby detachment of the film due to the warpage may be inhibited.

Preferably, the substrate is subjected to washing and polishing/smoothing treatments, such as a degreasing process for removing attached rolling oil, desmutting process for removing smut from the surface of the aluminum plate, and roughening process for roughening the surface of the aluminum plate, as required, before being used.

The porous aluminum oxide film formed by the anodization is an insulating oxide film having a plurality of pores formed by anodization, thereby ensuring high insulation. The anodization is performed by immersing the substrate, as anode, with a cathode in an electrolyte and applying a voltage between the anode and cathode. As for the cathode, carbon, aluminum, or the like is used.

There is not any specific restriction on anodization conditions, which are dependent on the type of electrolyte used. Appropriate anodization conditions include electrolyte concentration: 0.1 to 2 mol/L; solution temperature: 5 to 80° C.; current density: 0.005 to 0.60 A/cm²; voltage: 1 to 200V; and electrolyzing time: 3 to 500 minutes. There is not any specific restriction on the electrolyte and an acidic electrolyte that includes one or more acids, such as sulfuric acid, phosphoric acid, chromic acid, oxalic acid, malonic acid, sulfamic acid, benzenesulfonic acid, amidosulphonic acid, and the like is preferably used. In the case where one of such electrolytes is used, an electrolyte concentration of 0.2 to 1 mol/L, a solution temperature of 10 to 80° C., a current density of 0.05 to 0.30 A/cm², and a voltage of 30 to 150V are preferable.

Preferably, the porous aluminum oxide film includes a barrier layer portion and a porous layer portion in which the porous layer portion has a compressive strain at room temperature. Generally, it is known that the barrier layer has a compressive stress while the porous layer has a tensile stress, and the entire anodized film has a tensile stress if the film thickness is not less than several micrometers. In the mean time, a porous layer having a compressive stress may be produced by the used of the clad material described above and heat treatment to be described later. Consequently, it is possible to cause the entire anodized film to have a compressive stress even when the film thickness is not less than several micrometers, whereby cracking due to a difference in thermal expansion at the time of film forming is prevented and the film becomes an insulating film excellent in long term reliability near room temperature.

In this case, the magnitude of the compressive strain is preferably not less than 0.01%, more preferably not less than 0.05%, and further preferably not less than 0.10%. It is also preferable that the magnitude of the compressive strain is not greater than 0.25%. A compressive strain of less than 0.01% is too small to have an anti-cracking effect. Consequently, the anodized film formed as an insulating layer may have cracking, leading to reduced insulation if subjected to bending strains, long lasting temperature cycles, external shocks, or stresses in the final product.

On the other hand, an excessive compressive strain may cause detachment of the anodized film or a large compressive strain on the anodized film, thereby causing cracking in the film, lost of flatness due to surface rising, leading to reduced insulation. Thus, it is preferable that the compressive strain is not greater than 0.25%. It is known that the Yong's modulus of the anodized film is about 50 to 150 GPa, so that it is preferable that the magnitude of the compressive stress is 5 to 300 MPa.

Heat treatment may be performed after anodization. The heat treatment may cause the anodized film to have a compressive stress and anti-cracking property is improved. Thus, thermal resistance and insulation reliability are improved so that it is further suitably used as an insulating layer provided metal substrate. Preferably, the heat treatment temperature is 150° C. or higher. In the case where the clad material is used, heat treatment at a temperature of 300° C. or higher is preferable. The preheat treatment may reduce the amount of moisture included in the porous anodized film, whereby the insulation may be improved.

In a conventional substrate made of only aluminum, heat treatment at a temperature of 300° C. or higher causes a problem that the aluminum substrate loses the function of substrate due to softening of the aluminum or loses insulation due to cracking in the anodized film arising from the difference in thermal expansion coefficient between the aluminum and anodized film. But the use of a clad material of aluminum and a dissimilar metal allows heating at a temperature of 300° C. or higher.

The anodized film is an oxide film formed in a water solution, and it is known that moisture is held inside of the solid as described, for example, in T. Iijima et al., “Structure of Duplex Oxide Layer in Porous Alumina Studied by ²⁷AI MAS and MQMAS NMR”, Chemistry Letters, Vol. 34, No. 9, pp. 1286-1287, 2005. A solid NMR measurement of an anodized film identical to that described in the aforementioned document shows that the amount of moisture (OH group) inside of the solid of the anodized film is reduced when heat-treated at a temperature of 100° C. or higher, and the moisture reduction is significant when heat-treated at a temperature of 200° C. or higher. It is presumed that the heating may change the bonding state of Al—O and Al—OH, thereby inducing stress relaxation (annealing effect).

It is clear from the dehydration measurement of the anodized film conducted by the present inventors that most of the dehydration occurs from the room temperature to a temperature of about 300° C. In the case where the anodized film is used as the insulating film, heat treatment at a temperature of 300° C. or higher is extremely effective to improve the insulation since the greater the amount of moisture the poorer the insulation. The combination of the use of clad material of aluminum and a dissimilar metal and heat treatment at a temperature of 300° C. or higher may effectively cause annealing effect, whereby a high compressive strain and a less amount of moisture content that no conventional art has not been achieved may be realized. This allows an insulating layer provided metal substrate having a further high insulation reliability to be provided.

Preferably, the anodized film has a thickness of 3 to 50 μm from the viewpoint of electrical insulation. A film thickness of 3 μm or greater allows the film to have insulation and compressive stress at room temperature, whereby both the thermal resistance at the time of film forming and long term reliability may be obtained. Preferably, the film thickness is in the range from 5 μm to 30 μm, and more preferably in the range from 5 μm to 20 μm.

If the film thickness is extremely thin, the electrical insulation may not be secured and damage due to mechanical impact at the time of handling may not be prevented. Further, insulation and thermal resistance are reduced rapidly with increased temporal degradation. This is due to the fact that a thin film thickness causes relative increase in the influence of uneven surface of the anodized film, whereby cracking is likely to occur with the uneven surface as the starting point, reduced insulation due to metal deposits, intermetallic compounds, and metal oxides in the anodized film resulted from metal impurities included in the aluminum, in addition to relative increase in the influence of the voids, and increased damage due to external impact or stress whereby cracking is likely to occur. As such, an anodized film with a thickness of less than 3 μm is not suitable for applications of flexible thermal resistance substrates and roll-to-roll manufacturing due to reduced insulation.

An excessively thick film is undesirable as flexibility is reduced and anodization becomes costly and time consuming. Further, bending resistance and thermal distortion resistance are reduced. The reason for the reduction in bending resistance is assumed that, when the anodized film is bent, a stress distribution in the cross-sectional direction becomes large due to difference in tensile stress between the surface and interface with the aluminum, whereby a local stress concentration is likely to occur. The reason for the reduction in thermal distortion resistance is assumed that, when a tensile stress is exerted on the anodized film due to thermal expansion of the base material, a larger stress is exerted on the interface with the aluminum and the stress distribution becomes large in the cross-sectional direction, whereby a local stress concentration is likely to occur. As such, an anodized film with a thickness of greater than 50 μm is not suitable for applications of flexible thermal resistance substrates and roll-to-roll manufacturing due to reduced bending resistance and thermal distortion resistance. Further, the insulation reliability is reduced.

Formation of the composite structure layer 90 will be described next. First, the porous aluminum oxide film produced in the manner described above is immersed in an alkali metal silicate aqueous solution or the alkali metal silicate aqueous solution is applied on the porous aluminum oxide film. The range of 0.001 to 0.2 for the mass ratio of silicon to aluminum (Si/Al ratio) may be controlled by the use of an alkali metal silicate aqueous solution with a concentration of 5 mass % to 30 mass %, in which the use of an alkali metal silicate aqueous solution with a higher concentration will result in a higher Si/Al ratio, while the use of an alkali metal silicate aqueous solution with a lower concentration will result in a lower Si/Al ratio. In the case where the alkali metal in the alkali metal silicate aqueous solution is sodium, the mass ratio of sodium to aluminum (Na/Al ratio) may also be controlled by the use of an alkali metal silicate aqueous solution with a concentration of 5 mass % to 30 mass %.

The solution temperature of the alkali metal silicate aqueous solution is preferably 10 to 80° C., more preferably 20 to 60° C., and further preferably 20 to 40° C. A solution temperature higher than 80° C. is undesirable because the dissolution of the porous aluminum oxide film proceeds strongly and the pore walls of the porous aluminum oxide film become thin, whereby the strength of the porous aluminum oxide film itself is reduced, leading to cracking, reduced heat resistance, and reduced insulation. On the other hand, if the solution temperature of the alkali metal silicate aqueous solution becomes lower than 10° C., the viscosity of the solution is increased and the impregnation of the solution into the pores of the anodized film becomes difficult, whereby a desired composite structure may not be obtained, in addition to difficulty in handling. With respect to the solution temperature, the same applies to the case in which the solution is applied.

In terms of mass fraction, the concentration of the alkali metal silicate aqueous solution is preferably 5 mass % to 30 mass %, more preferably 10 mass % to 30 mass %, and particularly preferably 15 mass % to 30 mass %. If the concentration is too low, the amount of alkali metal silicate introduced into the pores of the anodized film is reduced, which may result in that a composite structure layer with a desired Si/Al ratio and a Na/Al ratio is not obtained. Also, in the case where the concentration is too high, the introduction of the solution into the pores becomes difficult, resulting in that a composite structure layer with a desired Si/Al ratio and a Na/Al ratio can not be obtained.

The viscosity of the alkali metal silicate aqueous solution at room temperature (22° C.) is preferably 1 mPa·s to 20 mPa·s, more preferably 2 mPa·s to 15 mPa·s, and particularly preferably 3 mPa·s to 15 mPa·s. If the viscosity is too low, the amount of alkali metal silicate introduced into the pores of the anodized film is reduced and it becomes difficult to obtain a composite structure layer with desired Si/Al and Na/Al ratios. Also, in the case where the viscosity is too high, the introduction of the solution into the pores of the anodized film becomes difficult and it is difficult to obtain a composite structure layer with desired Si/Al and Na/Al ratios.

When the porous aluminum oxide film is immersed into the alkali metal silicate aqueous solution, if the immersion time is prolonged, the basic alkali metal silicate aqueous solution dissolves the porous aluminum oxide film and the pore diameter is increased, whereby the introduced amount of alkali metal silicate is increased and the Si/Al ratio is increased. Although depending on the concentration and temperature of the alkali metal silicate aqueous solution used, the immersion time is preferable to be not greater than five minutes and more preferably not greater than one minute.

When coating the alkali metal silicate aqueous solution on the porous aluminum oxide film, there is not any specific restriction on the coating method and, for example, doctor blade method, wire bar method, gravure method, spraying method, dip coating method, spin coating method, capillary coating method, and the like may be used. When performing the coating by one of the coating methods described above, for example, by the spin coating method, it is preferable that the spin coating is performed immediately after the alkali metal silicate aqueous solution is dropped on the porous aluminum oxide film. If the solution is left at rest after being dropped, the porous aluminum oxide film is dissolved at the portion thereof where the solution is dropped and the pore diameter is increased, whereby the introduced amount of alkali metal silicate is increased, as in the case in which the porous aluminum oxide film is immersed in the alkali metal silicate aqueous solution for a longed time, so that it is undesirable. Preferably, the coating thickness is 0.01 to 2 μm, more preferably 0.05 to 1 μm, and further preferably 0.1 to 1 μm.

The embodiment in which only the inner pore surfaces of the porous aluminum oxide film 20 are covered, as illustrated in FIG. 1 or the embodiment in which an alkali metal silicate layer 31 is formed on the surface of the porous aluminum oxide film 20, as well as covering the inner surfaces of the pores of the porous aluminum oxide film 20, as illustrated in FIG. 2 may be controlled by the viscosity of the aqueous solution containing the alkali metal silicate, coating conditions, and the like, and the thickness of the alkali metal silicate layer 31 does not depend so much on the amount of aqueous solution containing alkali metal silicate introduced into the pores. The term “coating conditions” as used herein refers to such factors as coating speed (including withdrawal velocity in the dip coating method, rotation speed in the spin coating method, and the like), blade spacing in the doctor blade method, wire diameter in the wire bar method, discharge rate in the spray method, and the like.

The mass ratio of silicon to aluminum (Si/Al ratio) and the mass ratio of sodium to aluminum (Na/Al) may be controlled by such factors as pore diameter and void ratio (porosity) of the anodized film, type of electrolyte, and the like, other than the concentration of the alkali metal silicate aqueous solution, or by the coating conditions described above.

Preparation of the alkali metal silicate aqueous solution will now be described. As for the alkali metal silicate, sodium silicate, lithium silicate, and potassium silicate may be listed as examples. As for the method of producing those silicates, a wet method, dry method, or the like is known. They may be formed by a method in which silicon oxide is dissolved by sodium hydroxide, lithium hydroxide, and potassium hydroxide respectively. Further, various types of alkali metal silicates having different molar ratios are commercially available and these may also be used.

As for the sodium silicate, lithium silicate, and potassium silicate, various types of alkali metal silicates having different molar ratios are commercially available. As for the lithium silicate, for example, Lithium Silicate 35, Lithium Silicate 45, and Lithium Silicate 75 (available from Nissan Chemical Industries Ltd.) are known. As for the potassium silicate, Potassium Silicate No. 1 and Potassium Silicate No. 2 are commercially available.

As for the sodium silicate, Sodium Orthosilicate, Sodium Metasilicate, Sodium Silicate No. 1, Sodium Silicate No. 2, Sodium Silicate No. 3, and Sodium Silicate No. 4 are known and a high-molar sodium silicate in which the molar ratio of silicon is increased as high as a few dozens is also commercially available. By mixing the sodium silicate, lithium silicate, and potassium silicate with water at give ratios respectively, an alkali metal silicate aqueous solution with a concentration of 5 mass % to 30 mass % may be obtained. The viscosity of the coating liquid may be controlled by changing the additive amount of water, changing the solvent, or adding a viscosity modifier.

A boron-containing compound or a phosphorus-containing compound may be added to the alkali metal silicate aqueous solution. The addition of these compounds may further improve the water washability and power generation efficiency. The detailed mechanism for this phenomenon is still unclear, but it is assumed that the addition of the boron or phosphorus to the alkali metal silicate aqueous solution causes a change in microstructure of glass and the stability of alkali ions in the glass is increased. As a result, it is presumed that the liberation of the alkali ions is suppressed, whereby water washability and power generation efficiency are improved.

As for the boron source, borate salt, such as boric acid or sodium tetraborate may be listed as examples. Examples of phosphorus sources include phosphoric acid, peroxophosphoric acid, phosphonic acid, phosphinic acid, diphosphoric acid, triphosphoric acid, polyphosphoric acid, cyclo-triphosphoric acid, cyclo-tetraphosphoric acid, diphosphonic acid, and salts of these acids. Preferable examples include, for example, lithium phosphate, sodium phosphate, potassium phosphate, lithium hydrogen phosphate, ammonium phosphate, sodium hydrogen phosphate, calcium hydrogen phosphate, ammonium hydrogen phosphate, lithium dihydrogen phosphate, sodium dihydrogen phosphate, calcium dihydrogen phosphate, ammonium dihydrogen phosphate, sodium pyrophosphate, sodium triphosphate, and the like.

Lastly, heat treatment is performed after the immersion or coating. The dehydration temperature measurements performed by the present inventors using the thermogravimetric analysis technique and temperature desorption analysis technique show that the dehydration occurs at about 200° C. to 300° C. A temperature lower than 200° C. is undesirable, because the coating liquid is not sufficiently dried and an alkali metal silicate layer with high water resistance may not be formed. Heat treatment at a temperature lower than 300° C. results in a large amount of residual moisture in the alkali metal silicate layer and causes a problem that an impurity, such as carbonate, is formed on the surface by the reaction of the residual moisture with carbon dioxide or the like in the atmosphere or sodium molybdate is generated at the time of sputtering a Mo electrode. Accordingly, the heat treatment temperature is preferable to be not less than 200° C., more preferable not less than 300° C., and particularly preferable not less than 400° C.

As the heat treatment is performed at such a high temperature, the substrate used in the present invention is preferable to be a clad substrate formed of aluminum and a dissimilar metal combined together with an anodized film formed on a surface of the aluminum. It is known that clad substrates have a high thermal resistance such that cracking does not occur at a temperature of 400° C. or higher as described above. It is also known that the heat treatment at a temperature not less than 300° C. performed in advance may cause the anodized film to have a compressive stress which further improves the thermal resistance property and ensures long term insulation reliability. The heat treatment after the coating of the alkali metal silicate layer may serve the heat treatment required for dehydration of the alkali metal silicate layer and the heat treatment required for causing the anodized film to have compressive stress at the same time. On the other hand, a temperature exceeding 600° C. is undesirable because such temperature exceeds the glass transition temperature of the alkali metal silicate.

[Metal Substrate with an Insulating Layer of Second Embodiment]

An insulating layer provided metal substrate of a second embodiment of the present invention will be described in detail with reference to the accompanying drawings. FIG. 4 is a partially enlarged cross-sectional view of an insulating layer provided metal substrate of the second embodiment of the present invention. The insulating layer provided metal substrate includes a metal substrate having a metallic aluminum 11 on at least one surface, a composite structure layer 90′ formed of a porous aluminum oxide film 20 provided on the metallic aluminum 11 by anodization and an inorganic metal oxide film 30′ covering the surface 20a of the porous aluminum oxide film 20 and pore surfaces 20b of the porous aluminum oxide film 20, and an alkali metal silicate layer 31 formed on the composite structure layer 90′. The thickness of the composite structure layer 90′ is preferably 1 to 50 μm, more preferably 3 to 30 μm, and particularly preferably 5 to 20 μm.

The composite structure layer 90′ of the insulating layer provided metal substrate of the second embodiment includes substantially no alkali metal. The term “includes substantially no alkali metal” as used herein refers to that the composite structure layer 90′ does not include any alkali metal except for those unavoidably mixed therein, as impurities, from raw material or manufacturing process, or a small amount of alkali metal detected as noise in composition analysis. As illustrated in FIG. 4, the inorganic metal oxide film 30′ covers pore surfaces 20b and the surface 20a of the porous aluminum oxide film 20, whereby the entire porous aluminum oxide film 20 is completely covered by the inorganic metal oxide film 30′. Even in the case where the alkali metal silicate layer 31 is provided by coating, no coating liquid is impregnated into the pores of the porous anodized film 20, so that the alkali metal itself does not act as conductive carrier and the function as the insulating layer may be ensured. Further, as the composite structure layer 90′ is of a structure in which the surface 20a of the porous aluminum oxide film 20 is covered by the inorganic metal oxide film 30′, a planarity effect can be obtained and a defect in the substrate that will lead to reduced power generation efficiency of the photoelectric conversion device may be prevented, as well as reduced insulation, by preventing moisture adsorption.

For the inorganic metal oxide of the inorganic metal oxide film 30′, silicon oxide, aluminum oxide, titanium oxide and the like are preferably used, in which silicon oxide is more preferable. In the case of silicon oxide, the film may be formed by a liquid phase method (sol-gel method) using alkoxysilane. Hereinafter, description will be made by taking this case as example. As for the monomer, the starting material, for example, tetraalkoxysilane having four alkoxy groups may be used. As for the tetraalkoxysilane, tetramethoxysilane, tetraethoxysilane, tetraisopropoxysilane, tetrabutoxysilane, dimethoxy diethoxysilane, or the like may be preferably listed, which may be used solely or in combination of two or more types as appropriate.

The composite structure layer 90′ may be formed by applying an alkoxysilane solution. The alkoxysilane solution (coating liquid) may be prepared by mixing alkoxysilane and solvent. As for the solvent, for example, water, ethanol, methanol, and the like may be used. Further a combined solvent prepared by combining isopropyl alcohol, methyl ethyl ketone, or the like with these solvents.

The alkoxysilane solution may further include other components, such as various acids (e.g., hydrochloric acid, acetic acid, sulfuric acid, nitric acid, phosphoric acid, and the like), various bases (e.g., ammonia, sodium hydroxide, sodium hydrogen carbonate, and the like), a hardener (e.g., metal chelate compound, and the like), a viscosity modifier (e.g., polyvinyl alcohol, polyvinylpyrrolidone, and the like).

The solution temperature of the alkoxysilane solution is preferably 10 to 80° C., more preferably 20 to 60° C., and further preferably 20 to 40° C. A solution temperature higher than 80° C. is undesirable because the dissolution of the porous aluminum oxide film proceeds strongly and the pore walls of the porous aluminum oxide film become thin, whereby the strength of the porous aluminum oxide film itself is reduced, leading to cracking, reduced heat resistance, and reduced insulation. On the other hand, if the solution temperature of the alkoxysilane solution becomes lower than 10° C., the viscosity of the solution is increased and the impregnation of the solution into the pores of the anodized film becomes difficult, whereby a desired composite structure may not be obtained, in addition to difficulty in handling.

In terms of mass fraction, the concentration of the alkoxysilane solution is preferably 0.1 mass % to 30 mass %, more preferably 0.5 mass % to 30 mass %, and particularly preferably 1 mass % to 30 mass %. If the concentration is too low, the amount of alkoxysilane introduced into the pores of the anodized film is reduced and a composite structure layer may not be obtained. Also, in the case where the concentration is too high, the introduction of the alkoxysilane solution into the pores becomes difficult and a composite structure layer may not be obtained.

The viscosity of the alkoxysilane solution at room temperature (22° C.) is preferably 1 mPa·s to 20 mPa·s, more preferably 2 mPa·s to 15 mPa·s, and particularly preferably 3 mPa·s to 15 mPa·s. If the viscosity is too low, the amount of alkoxysilane introduced into the pores of the anodized film is reduced and it becomes difficult to obtain a composite structure layer. Also, in the case where the viscosity is too high, the introduction of the alkoxysilane solution into the pores of the anodized film becomes difficult and it is difficult to obtain a composite structure layer.

When applying the alkoxysilane solution prepared in the manner described above on the porous aluminum oxide film to form a coated film, there is not any specific restriction on the coating method and, for example, doctor blade method, wire bar method, gravure method, spraying method, dip coating method, spin coating method, capillary coating method, and the like may be used.

The inorganic metal oxide film 30′ may be provided so as to cover the pore surfaces 20b of the porous aluminum oxide film 20 and the surface 20a of the porous aluminum oxide film 20, as illustrated in FIG. 4, by controlling coating conditions as appropriate in addition to the temperature and viscosity of the alkoxysilane solution. The term “coating conditions” as used herein refers to such factors as coating speed (including withdrawal velocity in the dip coating method, rotation speed in the spin coating method, and the like), blade spacing in the doctor blade method, wire diameter in the wire bar method, discharge rate in the spray method, and the like.

After the film is coated, heating for a hydrolytic condensation reaction of the alkoxysilane in the coated film is performed. As the hydrolytic condensation reaction of the alkoxysilane proceeds by the sol-gel reaction, the condensate of alkoxysilane gradually becomes a high molecular mass. The heating temperature is preferably 50° C. to 200° C. and the reaction time is preferably five minutes to one hour. A heating temperature exceeding 200° C. causes an air gap to occur in alkoxysilane condensates.

The thickness of the inorganic metal oxide film after forming the inorganic metal oxide film (refers to the thickness of the inorganic metal oxide film covering the surface 20a of the porous aluminum oxide film 20, here) is preferably not greater than 300 nm, more preferably not greater than 200 nm, and particularly preferably not greater than 100 nm. If the thickness exceeds 300 nm, cracking is likely to occur and adhesion is reduced. On the other hand, if the inorganic metal oxide film is excessive thin, the effect of improving the affinity between the porous aluminum oxide film and the alkali metal silicate layer is reduced. Therefore, the thickness is preferably not less than 10 nm and more preferably not less than 20 nm.

The porous aluminum oxide film in the insulating layer provided metal substrate of the second embodiment may be formed in the same manner as that of the porous aluminum oxide film in the insulating layer provided metal substrate of the first embodiment.

A photoelectric conversion device using the insulating layer provided metal substrate of the present invention will now be described. (Note that although the description will be made of a case in which the insulating layer provided metal substrate of the first embodiment shown in FIG. 2 is used, the structure as the photoelectric conversion device is identical to the case where the insulating layer provided metal substrate of the second embodiment is used.) FIG. 5 is a schematic cross-sectional view of an embodiment of the photoelectric conversion device. As illustrated in FIG. 5, the photoelectric conversion device 1 is of a structure in which a composite structure layer 90 formed of a porous aluminum oxide film and an alkali metal silicate film, an alkali metal silicate layer 31, a lower electrode 40, a photoelectric conversion semiconductor layer 50 that generates a hole-electron pair by absorbing light, a buffer layer 60, a light transmitting conductive layer (transparent electrode) 70, and an upper electrode (grid electrode) 80 are layered in this order on a metal substrate 10. Note that the metal substrate 10 includes a metallic aluminum 11 thereon but omitted in FIG. 5.

There is not any specific restriction on the component of the lower electrode (back contact electrode) 40, and Mo, Cr, W, and a combination thereof are preferable, in which Mo or the like is particularly preferable. There is not any specific restriction on the thickness of the lower electrode (back contact electrode) 40 and a thickness of about 200 to about 1000 nm is preferable.

The photoelectric conversion semiconductor layer 50 is a compound semiconductor system photoelectric conversion semiconductor layer, and there is not any specific restriction on the major component (component with a content of 20% by mass or more) thereof, and from the viewpoint of high photoelectric conversion efficiency, a chalcogen compound semiconductor, a compound semiconductor having a chalcopyrite type structure, or a compound semiconductor having a defect stannite type structure is preferably used.

As for chalcogen compounds (compounds containing S, Se, Te), the following are preferable:
II-VI compounds: ZnS, ZnSe, ZnTe, CdS, CdSe, CdTe and the like;
I-III-VI₂ compounds: CuInSe₂, CuGaSe₂, Cu(In, Ga)Se₂, CuInS₂, CuGaS₂, Cu(In, Ga)(S, Se)₂, and the like; and
I-III₃-VI₅ compounds: CuIn₃Se₅, CuGa₃Se₅, Cu(In, Ga)₃Se₅, and the like.

As for compound semiconductors having a chalcopyrite type structure or a defect stannite type structure, the following are preferable:
I-III-VI₂ compounds: CuInSe₂, CuGaSe₂, Cu(In, Ga)Se₂, CuInS₂, CuGaSe₂, Cu(In, Ga)(S, Se)₂, and the like;
I-III₃-VI₅ compounds: CuIn₃Se₅, CuGa₃Se₅, Cu(In, Ga)₃Se₅, and the like.
   Here, (In, Ga) and (S, Se) represent (In₁₋ₓGaₓ) and (S_{1-y}Se_{y}) (where, x=0 to 1 and y=0 to 1).

There is not any specific restriction on the method of forming the photoelectric conversion semiconductor layer. For example, in the film forming of a CI(G)S photoelectric conversion semiconductor layer which includes Cu, In, (Ga), and S, selenization method or multi source deposition may be used. There is not any specific restriction on the thickness of the photoelectric conversion semiconductor layer, and a thickness of 1.0 to 3.0 μm is preferable and a thickness of 1.5 to 2.0 μm is particularly preferable.

There is not any specific restriction on the buffer layer 60, and it is preferable that the buffer layer 60 includes a metallic sulfide that includes at least one metal element selected from the group consisting of Cd, Zn, Sn, and In, such as Cds, ZnS, Zn(S, O) and/or Zn(S, O, OH), SnS, Sn(S, O) and/or Sn(S, O, OH), InS, In(S, O) and/or In(S, O, OH), and the like. The thickness of the buffer layer 60 is preferably 10 nm to 2 μm and more preferably 15 to 200 nm.

The light transmitting conductive layer (transparent electrode) 70 is a layer through which light is introduced and functions as an electrode through which electric current generated in the photoelectric conversion semiconductor layer 50 flows paired with the lower electrode 40. There is not any specific restriction on the composition of the light transmitting conductive layer 70, and n-ZnO such as ZnO:Al or the like is preferable. There is not any specific restriction on the thickness of the light transmitting conductive layer 70, and a thickness of 50 nm to 2 μm is preferable. There is not any specific restriction on the upper electrode (grid electrode) 80, and Al or the like may be preferably used. There is not any specific restriction on the thickness of the upper electrode 80, and a thickness of 0.1 to 3 μm is preferable.

Next, a semiconductor apparatus of the present invention will be described. The semiconductor apparatus of the present invention includes the insulating layer provided metal substrate according to the present invention and a semiconductor circuit formed on the substrate. Hereinafter, the description will be made by taking a photoelectric conversion apparatus as an example of the semiconductor apparatus. FIG. 6 is a schematic cross-sectional view of the photoelectric conversion apparatus according to an embodiment of the present invention (apparatus in which photoelectric conversion devices shown in FIG. 5 are integrated).

The photoelectric conversion apparatus 100 includes integrated semiconductor devices and forms a semiconductor circuit, each device having a composite structure layer 90 formed of a porous aluminum oxide film and an alkali metal silicate film, an alkali metal silicate layer 31, a lower electrode 40 (back contact electrode), a photoelectric conversion semiconductor layer 50, a buffer layer 60, and an upper electrode (transparent electrode) 80 layered in this order on a metal substrate 10.

The photoelectric conversion apparatus 100 has a first open groove 61 that runs through only the lower electrode 40, a second open groove 62 that runs through the photoelectric conversion semiconductor layer 50 and buffer layer 60, and a third open groove 63 that runs through the photoelectric conversion semiconductor layer 50, buffer layer, and upper electrode 80 in a cross-sectional view.

In the configuration described above, a structure in which the apparatus is separated into many devices C by the first to third open grooves 61 to 63 is obtained. Further, a structure in which the upper electrode 80 of a certain device C is serially connected to the lower electrode 40 of an adjacent device C may be obtained by filling the upper electrode 80 into the second open groove 62. That is, the semiconductor circuit is separated into a plurality of devices (cells) by a plurality of open grooves to form an integrated circuit in which the plurality of devices is electrically connected in series such that a voltage generated by each of the plurality of devices is added up. Here, the effective portion of the photoelectric conversion function is a region C′.

In the insulating property of the anodized film of the insulating layer provided metal substrate, if a voltage is applied to the anodized film such that the metal substrate 10 has a positive polarity, anodized film withstands a high voltage, showing very high insulation, in comparison with the case in which a voltage is applied such that the metal substrate 10 has a negative polarity. The reason for this phenomenon is not necessarily clear, but it is presumed that the barrier layer is growing thick while self-repairing defects present in the barrier layer. That is, it is presumed that the voltage application in a manner such that the metal substrate 10 has a positive polarity causes an electric field concentration at an electrically vulnerable defect portion and an anodization phenomenon occurs preferentially adjacent to the defect portion, whereby the defect self-repairing occurs preferentially and a defect-free barrier layer is grown with the passage of time. It is said that a self-repairing occurs in an Al electrolytic capacitor of high voltage specification in use as a capacitor.

Based on such phenomenon, the photoelectric conversion apparatus according to the present embodiment is configured such that the electric potential of the metal substrate 10 becomes higher than an average electric potential of the semiconductor circuit when the photoelectric conversion apparatus is activated. For example, the metal substrate 10 is short-circuited to the lower electrode 40 having a higher electric potential than an average electric potential of the semiconductor circuit in FIG. 6. Such configuration increases a region of the metal substrate 10 having a positive polarity with respect to the semiconductor circuit and a favorable insulating property may be realized with only the anodized film.

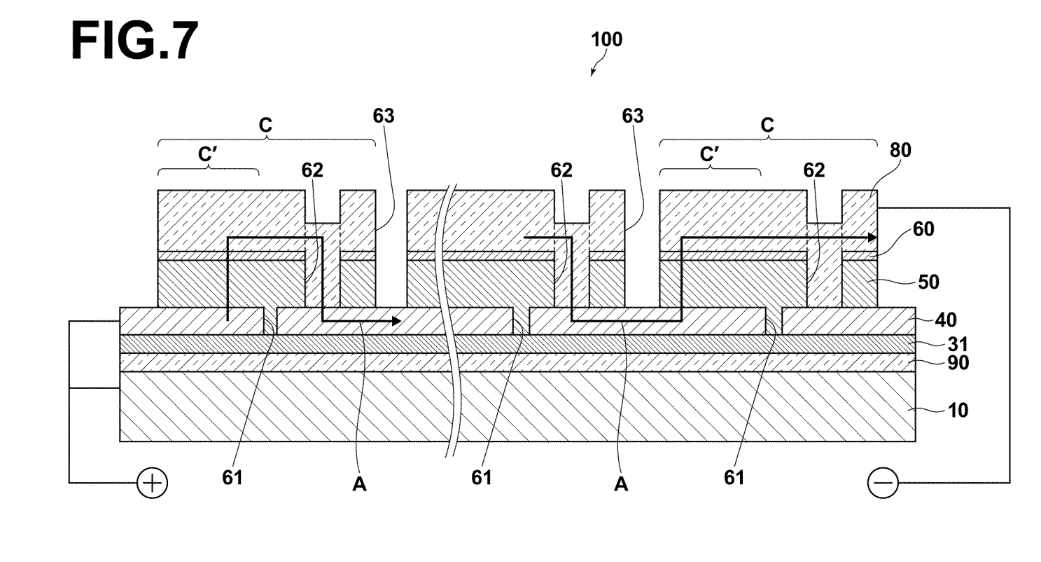

Further, the metal substrate 10 of the insulating layer provided metal substrate is preferably connected (short-circuited) to a portion of the semiconductor circuit which becomes the highest in electric potential when the semiconductor circuit is activated. FIG. 7 is a schematic cross-section view of the photoelectric conversion apparatus according to the present embodiment, illustrating a wiring example. The photoelectric conversion apparatus in FIG. 7 is configured such that an electric current flows in the arrow A direction. Thus, the metal substrate 10 is short-circuited to the lower electrode 40 which becomes highest in electric potential in FIG. 7. Such configuration allows the entire region of the metal substrate 10 to have a electric potential higher than the electric potential of the semiconductor circuit, whereby more favorable insulating property may be realized. FIG. 7 is a drawing illustrating a repetitive serial connection structure in an easily understandable manner and it should be understood that the connection of the negative extraction electrode is the upper electrode 80, as illustrated in the drawing, or the lower electrode 40 located under the second open groove 62.

The short-circuiting place is not limited to the lower electrode and it may be, for example, the upper electrode. Further, the short-circuiting place may be one of a plurality of photoelectric conversion devices C formed by segmentation having a highest voltage when activated and it may be, in particular, an electrode of the device (lower electrode or upper electrode). The short-circuiting method may be, for example, connection of the metal substrate 10 to the short-circuiting portion, such as the lower electrode 40 or the like, with a wire or connection of the metal substrate 10 to the lower electrode 40 by forming one pinhole in the anodized film. Hereinafter, the present invention will be described in more detail by way of Examples.

### EXAMPLES

### Examples of Metal Substrate with an Insulating Layer of First Embodiment

### (Preparation of Coating Liquids)

Coating liquids were prepared according to the prescription shown in Table 1. Mass ratios between the sodium silicate and lithium silicate shown in Table 1 are shown in Tables 2 and 3. The concentrations of the coating liquid are calculated from the mass ratios.

TABLE 1

| | | | | | | 85% | | | |
|---|---|---|---|---|---|---|---|---|---|
| | | | | | Boric | Phos- | | | |
| | Sodium Silicate | | Lithium Silicate | | Acid | Acid | Water | | |
| | | Amount | | Amount | Amount | Amount | Amount | Con. | Vis. |
| | Type | [g] | Type | [g] | [g] | [g] | [g] | [mass %] | [mPa · s] |
| C-Liq. 1 | No. 3 | 1 | Lithium Silicate 45 | 1 | 1 | | | 20.4 | 4.8 |
| C-Liq. 2 | No. 1 | 1 | Lithium Silicate 45 | 10 | 1 | | | 22.7 | 6.6 |
| C-Liq. 3 | No. 4 | 4 | Lithium Silicate 45 | 1 | 5 | | | 14.3 | 2.3 |
| C-Liq. 4 | No. 3 | 3 | | | 1 | | | 29.3 | 11.8 |
| C-Liq. 5 | No. 1 | 1 | | | 1 | | | 27.0 | 6.8 |
| C-Liq. 6 | H-Molar | 1 | | | | | | 15.3 | 5.3 |
| C-Liq. 7 | No. 3 | 1 | Lithium Silicate 45 | 1 | | 0.025 | 0.5 | 24.3 | 15.1 |
| C-Liq. 8 | No. 3 | 1 | Lithium Silicate 45 | 1 | 0.02 | | 0.5 | 24.3 | 13.8 |

TABLE 2

| | Mass Ratio | | |
|---|---|---|---|
| Sodium Silicate Type | Si0₂ | Na₂0 | Water |
| No. 1 | 37.0% | 17.0% | 46.0% |
| No. 3 | 29.0% | 10.0% | 61.0% |
| No. 4 | 23.9% | 6.3% | 69.8% |
| High Molar | 14.8% | 0.6% | 84.7% |

TABLE 3

| | Mass Ratio | | |
|---|---|---|---|
| Lithium Silicate Type | Si0₂ | Li₂0 | Water |
| Lithium Silicate 45 | 20.1% | 2.3% | 77.7% |

### Examples 1-1 to 1-8

Clad materials formed of 4N aluminum with a thickness of 30 μm and SUS430 with a thickness of 100 μm were anodized using the electrolytes shown in Table 4 under the conditions shown in Table 4 to produce anodized substrates. Coating Liquid 1 shown in Table 1 was dropped on the produced anodized substrates and alkali metal silicate layers were formed by spin coating. For Example 1-8, Coating Liquid 1 was dropped on the substrate, then substrate was left for five minutes, and an alkali metal silicate layer was formed by spin coating. After the layers were formed, the substrates were heat treated at 450° C. and dried.

### Comparative Example 1-1

An alkali metal silicate layer was formed on an anodized substrate produced in (Examples 1-1 to 1-8) by dropping the prepared Coating Liquid 1, leaving the substrate for ten minutes, and performing spin coating. After the layer was formed, the substrate was heat treated at 450° C. and dried.

### Comparative Example 1-2

A sodium supply layer was formed on an anodized substrate produced in (Examples 1-1 to 1-8) by dropping a 0.1 mol/L sodium hydroxide solution and performing spin coating immediately. After the layer was formed, the substrate was heat treated at 450° C. and dried.

### (Composition Measurements of Composite Structure Layer)

The porous aluminum oxide film was cut off, and the cross-section was lapped and subsequently polished using Cross-section Polisher (JEOL Ltd.). The composition analysis of the composite structure layer was performed using the Ultra 55 FE-SEM manufactured by Zeiss. For a sample with a polished cross-section, observation was performed from a direction perpendicular to the cross-section, and a semi-quantitative analysis was performed for a rectangular region of 500 nm in the depth direction and 10 μm in the surface parallel direction (region illustrated in FIG. 3) by Non-Standard method (ZAF method) with an accelerating voltage of 5 keV. The measurement range is from a position 0.5 μm inward from the outermost surface of the porous aluminum oxide film (surface of the porous aluminum oxide film 20 in FIG. 3) to the position 0.5 μm toward the surface from the interface between the porous aluminum oxide film 20 and metallic aluminum 11. Using Na-Kα peak near 1041 eV, Al—Kα peak near 1486 eV, and Si—Kα peak near 1739 eV, average composition at any position in the depth direction within the 500 nm range was measured.

### (Water Washability Evaluation-Residual Na Ratio)

The substrates produced in (Examples 1-1 to 1-8) and (Comparative Examples 1-1 to 1-2) were immersed in pure water at room temperature for three minutes and an amount of Na before and after the immersion was measured by measuring intensity ratio of Na-Kα peaks near 1041 eV by XRF before and after the immersion. That is, the amount of Na was measured by measuring the amount of NaKα radiation by an XRF measuring system (50 kV, 60 mA). When the amount of Na before the immersion is taken as 1, the ratio of the amount of Na after the three-minute immersion was determined as the residual Na ratio. As the penetration depth of the incident X-rays is about 10 to 20 μm, the entire amount of Na included in the porous anodized aluminum film may be evaluated.

### (Manufacture of Solar Cell)

Mo was formed on each substrate produced in (Examples 1-1 to 1-8) and (Comparative Examples 1-1 to 1-2) by DC sputtering with a thickness of 800 nm. A CIGS solar cell was formed on the Mo electrode. In the present example, granular raw materials of high purity supper and indium (purity of 99.9999%), high purity Ga (purity of 99.999%), and high purity Se (purity of 99.999%) were used as the deposition sources. A chromel-alumel thermocouple was used for monitoring the substrate temperature. The main vacuum chamber was evacuated to 10⁻⁶ Torr (1.3×10⁻³ Pa) and then a CIGS thin film was formed by controlling deposition rate of each deposition source with a thickness of about 1.8 μm under the film forming condition of maximum substrate temperature of 530° C. Then, as the buffer layer, a CdS thin film was deposited about 90 nm by solution-growth technique followed by the formation of a 0.6 μm thick transparent conductive film of ZnO:Al by DC sputtering. Finally, as the upper electrode, an Al grid electrode was formed by deposition to complete the manufacture of the solar cell.

### (Power Generation Efficiency Measurements)

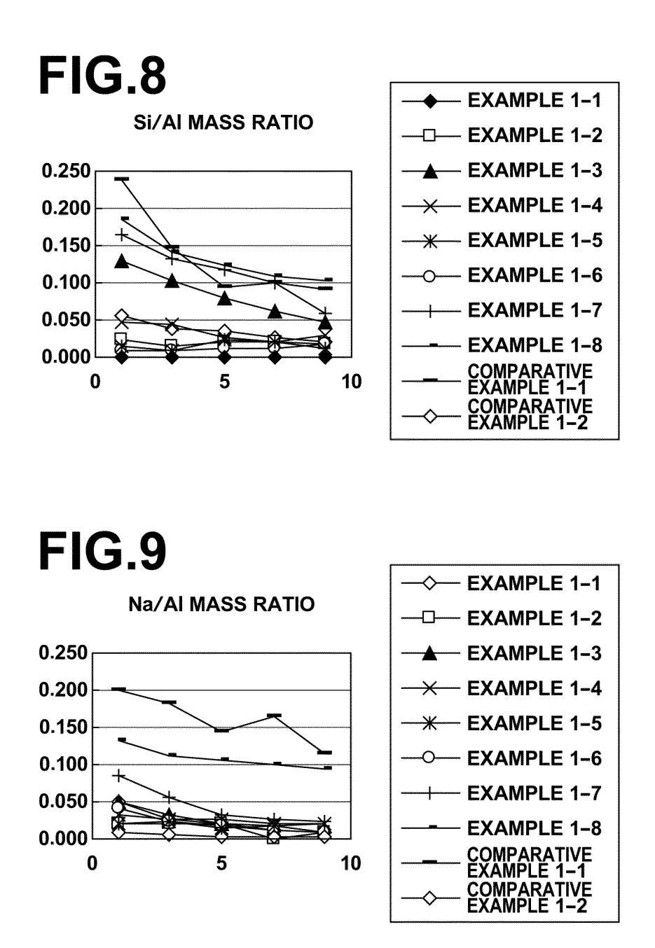

Pseudo solar light with air mass (AM)=1.5, 100 mW/cm² was directed to each manufactured solar cell (area of 0.5 cm²) to measure the energy conversion efficiency. Eight samples were provided for each example and comparative example. With respect to each photoelectric conversion device, photoelectric conversion efficiency was measured under the condition described above. Among the measured values, a median value is determined to be the conversion efficiency of the photoelectric conversion device of each example and comparative example. Measurement results of mass ratios of Si or Na to Al measured by the method described above, anodization conditions together with water washability evaluations and power generation efficiencies are shown in Table 4, and mass ratios of Si to Al and mass ratios of Na to Al are shown in FIGS. 8 and 9 respectively.

TABLE 4

| | | | | | | Si/Al Mass Ratio | | | | |
|---|---|---|---|---|---|---|---|---|---|---|
| | Substrate Manufacturing Conditions | | | | | Position in Depth | | | | |
| | Anodization Conditions | | | | Heat | Direction from Surface | | | | |
| | | Temp. | Vol. | Coating | Treat | [μm] | | | | |
| | Acid | [° C.] | [V] | Condition | [° C.] | 1 | 3 | 5 | 7 | 9 |
| Example | Malonic | 80 | 80 | C-Liq. 1 | 450 | 0.056 | 0.037 | 0.034 | 0.028 | 0.021 |
| 1-1 | (1 M/L) | | | | | | | | | |
| Example | Oxalic | 16 | 40 | C-Liq. 1 | 450 | 0.022 | 0.016 | 0.022 | 0.021 | 0.017 |
| 1-2 | (0.5 M/L) | | | | | | | | | |
| Example | Sulfuric | 35 | 13 | C-Liq. 1 | 450 | 0.130 | 0.104 | 0.081 | 0.062 | 0.048 |
| 1-3 | (1.7 M/L) | | | | | | | | | |
| Example | Oxalic | 50 | 40 | C-Liq. 1 | 450 | 0.046 | 0.045 | 0.026 | 0.021 | 0.031 |
| 1-4 | (0.5 M/L) | | | | | | | | | |
| Example | Malonic | 50 | 80 | C-Liq. 1 | 450 | 0.015 | 0.010 | 0.023 | 0.020 | 0.012 |
| 1-5 | (1 M/L) | | | | | | | | | |
| Example | Malonic | 50 | 135 | C-Liq. 1 | 450 | 0.010 | 0.009 | 0.011 | 0.010 | 0.018 |
| 1-6 | (1 M/L) | | | | | | | | | |
| Example | Sulfuric | 35 | 10 | C-Liq. 1 | 450 | 0.165 | 0.132 | 0.117 | 0.099 | 0.058 |
| 1-7 | (1.7 M/L) | | | | | | | | | |
| Example | Oxalic | 50 | 40 | C-Liq. 1 | 450 | 0.186 | 0.141 | 0.124 | 0.108 | 0.103 |
| 1-8 | (0.5 M/L) | | | 5m-Immer | | | | | | |
| C/Exam | Malonic | 80 | 80 | C-Liq. 1 | 450 | 0.237 | 0.146 | 0.094 | 0.100 | 0.091 |
| 1-1 | (1 M/L) | | | 10m-Immer. | | | | | | |
| C/Exam | Malonic | 80 | 80 | NaOH | 450 | Not | Not | Not | Not | Not |
| 1-2 | (1 M/L) | | | | | Det. | Det. | Det. | Det. | Det. |

| | Na/Al Mass Ratio | | | | | | |
|---|---|---|---|---|---|---|---|
| | Position in Depth | | | | | W/Wash. | |
| | Direction from Surface | | | | | Residual | P/G |
| | [μm] | | | | | Na Ratio | Eff. |
| | 1 | 3 | 5 | 7 | 9 | [%] | [%] |
| Example | 0.051 | 0.026 | 0.021 | 0.018 | 0.009 | 83 | 13.1 |
| 1-1 | | | | | | | |
| Example | 0.019 | 0.020 | 0.022 | 0.001 | 0.009 | 81 | 14.5 |
| 1-2 | | | | | | | |
| Example | 0.049 | 0.032 | 0.019 | 0.011 | 0.008 | 79 | 13.2 |
| 1-3 | | | | | | | |
| Example | 0.033 | 0.025 | 0.027 | 0.020 | 0.022 | 86 | 14.3 |
| 1-4 | | | | | | | |
| Example | 0.020 | 0.022 | 0.016 | 0.018 | 0.022 | 84 | 14.4 |
| 1-5 | | | | | | | |
| Example | 0.041 | 0.024 | 0.018 | 0.013 | 0.008 | 83 | 14.2 |
| 1-6 | | | | | | | |
| Example | 0.084 | 0.056 | 0.031 | 0.027 | 0.025 | 80 | 13.1 |
| 1-7 | | | | | | | |
| Example | 0.132 | 0.112 | 0.105 | 0.101 | 0.094 | 79 | 10.5 |
| 1-8 | | | | | | | |
| C/Exam | 0.201 | 0.182 | 0.143 | 0.165 | 0.114 | 76 | 5.7 |
| 1-1 | | | | | | | |
| C/Exam | 0.008 | 0.007 | 0.004 | 0.002 | 0.002 | 8 | 4.7 |
| 1-2 | | | | | | | |

As shown in Table 4, it is known that the Si/Al ratio and Na/Al ratio in the composite structure layer may be set to 0.001 to 0.2 and 0.001 to 0.1 respectively by the use of high concentration alkali metal silicate aqueous solutions. Further, the Si/Al ratio and Na/Al ratio may also be changed by changing the anodization conditions even with the use of the same high concentration coating liquid. Significantly high efficiencies are obtained from Examples 1-1 to 1-8 in comparison with Comparative Examples 1-1 to 1-2. Example 1-8 with a Na/Al ratio greater than 0.1 has the lowest power generation efficiency among the examples, but still the efficiency is near doubled in comparison with the comparative examples. The residual Na ratio of each of Examples 1-1 to 1-8 is not less than 70%, showing that the elution of Na is suppressed. That is, it is presumed that high efficiency is obtained because Na water washability is given and Na is supplied sufficiently to the CIGS.

On the other hand, when the substrate is immersed in the coating liquid for ten minutes, the Si/Al ratio exceeds 0.2 at a position 1 μm from the surface in the depth direction, as shown in Comparative Example 1-1, and leakage current is increased. It is assumed that this is due to the prolonged immersion time which caused thinned walls of pores of the porous aluminum oxide film and reduced strength of the porous aluminum oxide film itself, thereby leading to reduced insulation. Comparative Example 1-2 is an example provided with a sodium supply layer on the porous aluminum oxide film has a low residual Na amount ratio and an insulation breakdown occurred as it does not include a composite structure layer with alkali metal silicate film formed on the pore surfaces of the porous aluminum oxide film. It is presumed that, in Comparative Examples 1-1 and 1-2, the wall thickness of the anodized film is reduced and the insulation is reduced due to cracking in the anodized film or the like.

### Examples 2-1 to 2-7

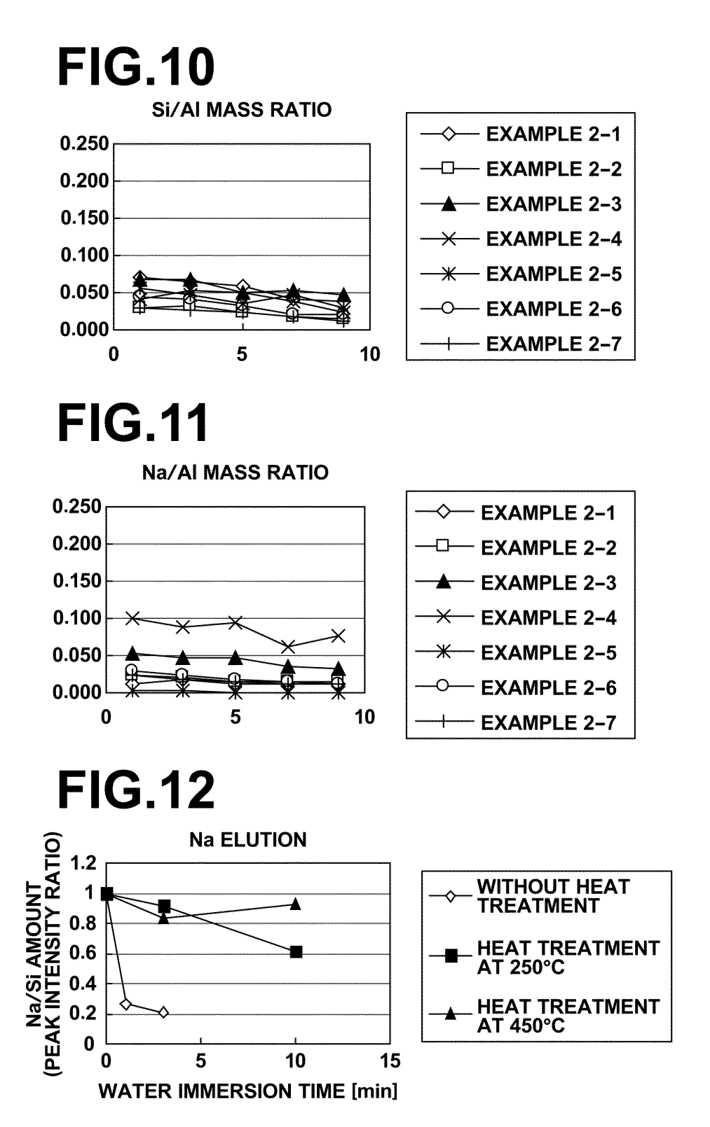

Clad materials formed of 4N aluminum with a thickness of 30 μm and SUS430 with a thickness of 100 μm were anodized using the electrolytes shown in Table 5 under the conditions shown in Table 5 to produce anodized substrates. Coating Liquids 2 to 8 shown in Table 1 were dropped on the produced anodized substrates and alkali metal silicate layers were formed by spin coating. After the layers were formed, the substrates were heat treated at 450° C. and dried. As in the example 1 series, measurement results of mass ratios of Si or Na to Al, anodization conditions together with water washability evaluations and power generation efficiencies are shown in Table 5, and mass ratios of Si to Al and mass ratios of Na to Al are shown in FIGS. 10 and 11 respectively.

TABLE 5

| | | | | | | Si/Al Mass Ratio | | | | |
|---|---|---|---|---|---|---|---|---|---|---|
| | Substrate Manufacturing Conditions | | | | | Position in Depth | | | | |
| | Anodization Conditions | | | | Heat | Direction from Surface | | | | |
| | | Temp. | Vol. | Coating | Treat | [μm] | | | | |
| | Acid | [° C.] | [V] | Condition | [° C.] | 1 | 3 | 5 | 7 | 9 |
| Example | Malonic | 80 | 80 | C-Liq. 2 | 450 | 0.070 | 0.065 | 0.059 | 0.041 | 0.037 |
| 2-1 | (1 M/L) | | | | | | | | | |
| Example | Oxalic | 50 | 40 | C-Liq. 3 | 450 | 0.030 | 0.031 | 0.025 | 0.017 | 0.016 |
| 2-2 | (0.5 M/L) | | | | | | | | | |
| Example | Malonic | 80 | 80 | C-Liq. 4 | 450 | 0.069 | 0.068 | 0.050 | 0.054 | 0.046 |
| 2-3 | (1 M/L) | | | | | | | | | |
| Example | Malonic | 80 | 80 | C-Liq. 5 | 450 | 0.041 | 0.052 | 0.049 | 0.039 | 0.024 |
| 2-4 | (1 M/L) | | | | | | | | | |
| Example | Malonic | 50 | 80 | C-Liq. 6 | 450 | 0.056 | 0.046 | 0.035 | 0.047 | 0.031 |
| 2-5 | (1 M/L) | | | | | | | | | |
| Example | Oxalic | 50 | 40 | C-Liq. 7 | 450 | 0.045 | 0.042 | 0.032 | 0.022 | 0.021 |
| 2-6 | (0.5 M/L) | | | | | | | | | |
| Example | Oxalic | 50 | 40 | C-Liq. 8 | 450 | 0.029 | 0.026 | 0.024 | 0.019 | 0.013 |
| 2-7 | (0.5 M/L) | | | | | | | | | |

| | Na/Al Mass Ratio | | | | | | |
|---|---|---|---|---|---|---|---|
| | Position in Depth | | | | | W/Wash. | |
| | Direction from Surface | | | | | Residual | P/G |
| | [μm] | | | | | Na Ratio | Eff. |
| | 1 | 3 | 5 | 7 | 9 | [%] | [%] |
| Example | 0.013 | 0.017 | 0.011 | 0.013 | 0.013 | 84 | 14.5 |
| 2-1 | | | | | | | |
| Example | 0.024 | 0.021 | 0.015 | 0.014 | 0.015 | 87 | 14.3 |
| 2-2 | | | | | | | |
| Example | 0.054 | 0.046 | 0.048 | 0.036 | 0.032 | 73 | 12.7 |
| 2-3 | | | | | | | |
| Example | 0.099 | 0.088 | 0.094 | 0.063 | 0.075 | 68 | 12.6 |
| 2-4 | | | | | | | |
| Example | 0.002 | 0.002 | 0.001 | 0.001 | 0.001 | 96 | 12.8 |
| 2-5 | | | | | | | |
| Example | 0.028 | 0.025 | 0.019 | 0.016 | 0.013 | 96 | 15.2 |
| 2-6 | | | | | | | |
| Example | 0.025 | 0.019 | 0.016 | 0.012 | 0.011 | 98 | 15.3 |
| 2-7 | | | | | | | |

Examples 2-1 to 2-7 used coating liquids of different concentrations and compositions. As shown in Table 1 and 5, the higher the concentration of the alkali metal silicate, the higher the viscosity, and the Si/Al ratio and Na/Al ratio tended to increase. Therefore, by regulating the concentration and composition of the alkali metal silicate, desirable Si/Al ratio and Na/Al ratio were obtained. The residual Na ratio of each example is not less than 68%, showing favorable water washability. Almost doubled power generation efficiency was obtained in comparison with comparative examples. Examples 2-3 to 2-5, which did not include lithium, had low power generation efficiencies in comparison with Examples 1-1 to 1-7, 2-1, and 2-2 which include lithium in addition to sodium. Examples 2-6 and 2-7 which include boron or phosphorus had the highest power generation efficiency of all the examples.

### Examples 3-1 to 3-6

Clad materials formed of 4N aluminum with a thickness of 30 μm and SUS430 with a thickness of 100 μm were anodized using 80° C., 1M/L malonic acid electrolyte under, a constant voltage of 80V to produce anodized substrates having a porous aluminum oxide film formed thereon with a thickness of 10 μm. Then, alkali metal silicate layers were formed on the substrates by dropping Coating Liquid 1 in Table 1 and immediately performing spin coating. When performing the spin coating, the film thickness is controlled to 0.1 to 2 μm by regulating the rotating speed of the spin coating in a range from 50 rpm to 5000 rpm. After the layers were formed, the substrates were heat treated at 450° C. and dried.

### (Heat Resistance Evaluation)

The substrates produced in the manner described above were subjected to crack generation test in which the substrates were heated rapidly from room temperature to each test temperature at 500K/min and cooled down to room temperature after being kept to each test temperature for fifteen minutes to check to see whether or not a crack was observed in the porous aluminum oxide film. Crack observation was performed by visual inspection of the substrates as substrates with a composite structure layer and by observing the composite structure layers with an optical microscope in which the composite structure layers were taken out by dissolving and removing the metal substrates. An iodine methanol solution was used for the dissolution and removal of the metal substrates. The crack generation evaluations by visual inspection and optical microscope observation were made based on the following criteria:
A: no crack generation is observed by the visual inspection and optical microscope observation;
B: no crack generation is observed by visual inspection but crack generation is observed by optical microscope observation; and
C: crack generation is observed both by visual inspection and optical microscope observation.
   The results of the test are shown in Table 6. Note that the Comparative Example 3-1 indicates heat resistance evaluations of the clad substrate with an anodized film itself.

TABLE 6

| | | | Thickness of | | | | | | |
|---|---|---|---|---|---|---|---|---|---|
| | | | Alkali Metal | Heat | | | | | Appearance |
| | | | Silicate Layer | Treat | Thermal Crack Resistance | | | | of Silicate |
| | Substrate | C-Liq. | [μm] | [° C.] | 450° C. | 500° C. | 550° C. | 575° C. | Layer |
| Example 3-1 | 4N Aluminum/SUS | C-Liq. 1 | 0.1 | 450 | A | A | A | B | |
| Example 3-2 | Malonic acid | C-Liq. 1 | 0.3 | 450 | A | A | A | B | |
| Example 3-3 | (1M/L) | C-Liq. 1 | 0.7 | 450 | A | A | A | B | |
| Example 3-4 | 80° C. 80 V | C-Liq. 1 | 1 | 450 | A | A | A | B | |
| Example 3-5 | | C-Liq. 1 | 1.4 | 450 | A | A | B | C | Crack |
| Example 3-6 | | C-Liq. 1 | 2 | 450 | A | B | C | C | Foam |
| C/Exam 3-1 | | Not Used | — | — | A | A | A | B | |

As shown in Table 6, the thermal crack resistance tends to be decreased as the thickness of the alkali metal silicate layer is increased. By the rapid temperature increase to 550° C., a crack is generated in the alkali metal silicate layer of Example 3-5 and a foam formation was observed in the alkali metal silicate layer of Example 3-6. Practically no such rapid temperature increase occurs in normal use, but the thickness of the alkali metal silicate layer is preferably not greater than 1.4 μm and more preferably not greater than 1 μm from the view point of heat resistance.

Samples of anodized substrate having the composite structure layer of Example 1-1, first of which was not subjected to heat treatment, second of which was heat treated at 250° C., and third of which was heat treated at 450° C., were immersed in pure water to evaluate the amount of Na with immersion time using XRF. The results are shown in FIG. 12. It is known that most of the sodium is lost from the sample without heat treatment after about one minute, while sodium is stably present in those subjected to heat treatment. Comparison between heat treatment temperatures of 250 and 450° C. shows that the latter has less amount of change, indicating that the higher the temperature the more stable is the sodium state.

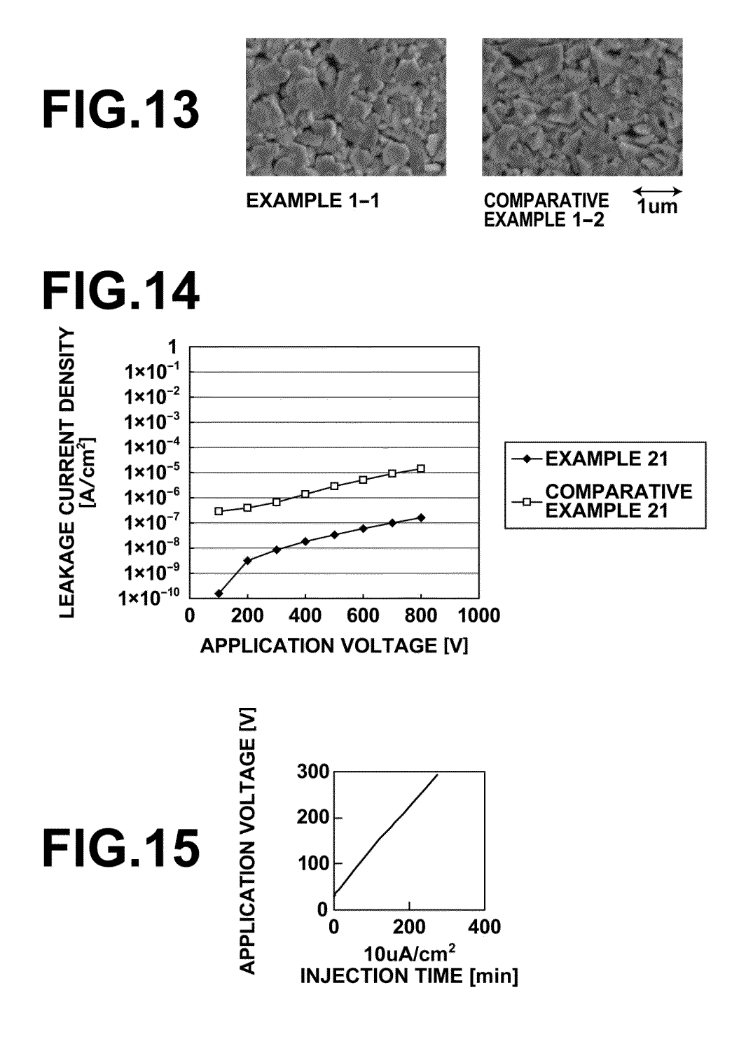

FIG. 13 shows electron microscope photographs of CIGS crystals of Example 1-1 and Comparative Example 1-2. As is clear from the electron microscope photographs of two CIGS crystals, it is known that the use of the insulating layer provided metal substrate of the first embodiment allows sodium to be diffused into the CIGS layer and the particle diameter of the CIGS crystal is increased. As a result, a solar cell having high energy conversion efficiency may be obtained.

[Examples of Metal Substrate with an Insulating Layer of Second Embodiment]

### (Preparation of Coating Liquids)

Coating liquids A and B were prepared according to the prescription shown in Tables 7 and 8 respectively.

TABLE 7
Coating Liquid A

| Reagents | Mass[g] |
|---|---|
| Pure Water | 3.92 |
| 35% HCl | 0.05 |
| Ethanol | 2.09 |
| Tetraethoxysilane | 4.17 |

TABLE 8
Coating Liquid B

| Reagents | Mass[g] |
|---|---|
| Lithium Silicate | 10 |
| (Nissan Chemical, Lithium Silicate 45) | |
| Sodium Silicate | 10 |
| (Showa Chemical, No. 3 Sodium Silicate) | |
| Pure Water | 5 |

### Example 21

A clad material formed of 4N aluminum with a thickness of 30 μm and SUS430 with a thickness of 100 μm was anodized using 50° C., 0.5M/L oxalic acid electrolyte under a constant voltage of 40V to produce an anodized substrate. A composite structure layer of silicon oxide and porous anodized film was formed by dropping Coating Liquid A shown in Table 7 on the produced anodized substrate, performing spin coating, and performing heat treatment at 150° C. for 30 minutes. Then, an alkali metal silicate layer was further formed by dropping Coating Liquid B, performing spin coating, and performing heat treatment at 450° C. for 30 minutes.

### Comparative Example 21

An alkali metal silicate layer was formed by dropping Coating Liquid B on the porous oxide substrate produced in (Example 1), performing spin coating, and performing heat treatment at 450° C. for 30 minutes. The coating liquids and heat treatment temperatures of Example 21 and Comparative Example 21 are shown in Table 9.

TABLE 9

| | Coating 1 | H-Treat 1 | Coating 2 | H-Treat 2 |
|---|---|---|---|---|
| Example 21 | C-Liq. A | 150° C. | C-Liq. B | 450° C. |
| C/Example 21 | C-Liq. B | 450° C. | — | — |

(Evaluation)

(Electrical Insulation)

An upper gold electrode with a diameter of 3.6 mm was formed on each substrate produced in Example 21 and Comparative Example 21. A heat treatment was performed in dry nitrogen atmosphere to dry the moisture adsorbed on the anodized film and a voltage of one volt was applied with the produced substrate being set to a positive polarity under the dried nitrogen atmosphere and the applied voltage was incremented by one volt. Current values measured in increments of 100V are shown in FIG. 14. As shown in FIG. 14, Example 21 had leakage currents of not greater than 1×10⁻⁸ A/cm² at 200V and not greater than 1×10⁻⁶ A/cm² at 800V. On the other hand, Comparative Example 21 had leakage currents of not less than 1×10⁻⁷ A/cm² at 200V and not less than 1×10⁻⁵ A/cm² at 800V, showing significantly low insulation.

As is clear from the aforementioned examples, the insulating layer provided metal substrate of the second embodiment does not substantially include an alkali metal so that there is no such case in which the alkali metal itself acts as a conductive carrier. Further, the porous aluminum oxide film of the composite structure layer and pore surfaces of the porous aluminum oxide film are covered by an inorganic metal oxide film, so that moisture is unlikely to be adsorbed, whereby the function as an insulating layer can be improved.

### Photoelectric Conversion Apparatus

### Example 31

A clad material formed of 4N aluminum with a thickness of 30 μm and SUS430 with a thickness of 100 μm was anodized using 50° C., 0.5M/L oxalic acid electrolyte under a constant voltage of 40V to produce an anodized substrate. An alkali metal silicate layer was formed by dropping Coating Liquid B shown in Table 8 on the produced anodized substrate, performing spin coating, and performing heat treatment at 450° C. for 30 minutes. Then, an upper gold electrode with a diameter of 3.6 was formed on the produced alkali metal silicate layer. A 10 μA/cm² electric current was applied for 275 minutes in the atmosphere with humidity of 50% with the substrate being set to a positive polarity. A plot diagram with the horizontal axis representing the 10 μA/cm² current application time and the vertical axis representing the applied voltage is shown in FIG. 15.

### Example 32

A sample was produced in the same manner as in Example 31 and a 10 μA/cm² electric current was applied for 275 minutes with the substrate being set to a negative polarity.

### (Evaluation)

### (Barrier Layer Cross-section Observation)

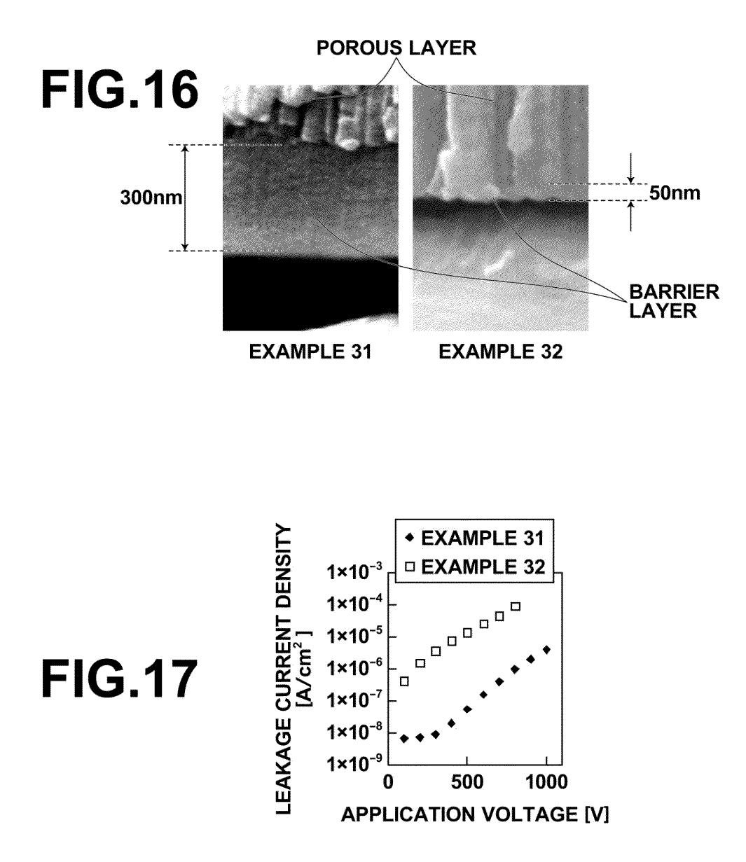

Cross-sectional images of fracture cross-sections of the substrates produced in Example 31 and Example 32 observed from a direction perpendicular to the cross-sections with an Ultra 55 FE-SEM manufactured by Zeiss are shown in FIG. 16. As shown in FIG. 16, while Example 32 has a barrier layer of about 50 nm, Example 31 has a barrier layer of about 300 nm. The reason why Example 31 has a thick barrier layer is thought to be that the application of 10 μA/cm² electric current for 275 minutes has caused progress in anodization. Here, the injected charge amount is 0.165 C/cm².

### (Evaluation)

### (Electrical Insulation)

With the substrates produced in Examples 31 and 32 being set to a positive polarity, a voltage of one volt was applied and the applied voltage was incremented by one volt under the atmosphere with humidity of 50%. Current values measured in increments of 100V are shown in FIG. 17. As shown in FIG. 17, Example 31 had leakage currents of not greater than 1×10⁻⁸ A/cm² at 200V and not greater than 1×10⁻⁶ A/cm² at 800V. On the other hand, Example 32 had leakage currents of not less than 1×10⁻⁶ A/cm² at 200V and not less than 1×10⁻⁵ A/cm² at 800V, showing significantly low insulation.

As is clear from the examples, if the insulating layer provided metal substrate of the present invention was used and the metal substrate was connected to a portion of the semiconductor circuit having a higher electric potential than an average electric potential of the semiconductor circuit, as in Example 31, the thickness of the barrier layer was increased and ion conduction in the barrier layer was suppressed, whereby the insulation was greatly increased. Thus, by connecting the metal substrate with an insulation layer of the present invention in the manner described above, electrical insulation can be made further reliable.

What is claimed is:

1. An insulating layer provided metal substrate, comprising a metal substrate having a metallic aluminum on at least one surface and a composite structure layer formed of a porous aluminum oxide film provided on the metallic aluminum by anodization and an alkali metal silicate film covering the porous aluminum oxide film and pore surfaces of the porous aluminum oxide film,
wherein the mass ratio of silicon to aluminum in the composite structure layer is 0.001 to 0.2 at an arbitrary position within a region between a position 1 μm to the composite structure layer side in thickness from the interface between the composite structure layer and the metallic aluminum and a position 1 μm to the composite structure layer side in thickness from the interface between the composite structure layer and an upper layer on the opposite side of the metallic aluminum.

2. The insulating layer provided metal substrate of claim 1, wherein the alkali metal of the alkali metal silicate film comprises at least sodium, and the mass ratio of sodium to aluminum in the composite structure layer is 0.001 to 0.1 at an arbitrary position within a region between a position 1 μm to the composite structure layer side in thickness from the interface between the composite structure layer and the metallic aluminum and a position 1 μm to the composite structure layer side in thickness from the interface between the composite structure layer and an upper layer on the opposite side of the metallic aluminum.

3. The insulating layer provided metal substrate of claim 2, wherein the alkali metal of the alkali metal silicate film comprises sodium and lithium or potassium.

4. The insulating layer provided metal substrate of claim 2, wherein the alkali metal silicate film includes boron or phosphorus.

5. The insulating layer provided metal substrate of claim 3, wherein the alkali metal silicate film includes boron or phosphorus.

6. The insulating layer provided metal substrate of claim 1, wherein the metal substrate comprises an alkali metal silicate layer provided on the composite structure layer and covering the porous aluminum oxide film at end faces.

7. An insulating layer provided metal substrate, comprising a metal substrate having a metallic aluminum on at least one surface, a composite structure layer formed of a porous aluminum oxide film provided on the metallic aluminum by anodization and an inorganic metal oxide film covering the surface of the porous aluminum oxide film and pore surfaces of the porous aluminum oxide film, and an alkali metal silicate layer formed on the composite structure layer,
wherein the composite structure layer does not substantially include any alkali metal.

8. The insulating layer provided metal substrate of claim 7, wherein the inorganic metal oxide of the inorganic metal oxide film is silicon oxide.

9. The insulating layer provided metal substrate of claim 7, wherein the thickness of the inorganic metal oxide film covering the surface of the porous aluminum oxide film is not greater than 300 nm.

10. The insulating layer provided metal substrate of claim 8, wherein the thickness of the inorganic metal oxide film covering the surface of the porous aluminum oxide film is not greater than 300 nm.

11. The insulating layer provided metal substrate of claim 6, wherein the thickness of the alkali metal silicate layer is not greater than 1 μm.

12. The insulating layer provided metal substrate of claim 7, wherein the thickness of the alkali metal silicate layer is not greater than 1 μm.

13. The insulating layer provided metal substrate of claim 1, wherein the metal substrate is a clad material in which an aluminum plate is integrated on one or both surfaces of an aluminum, stainless steel, or steel plate.

14. The insulating layer provided metal substrate of claim 7, wherein the metal substrate is a clad material in which an aluminum plate is integrated on one or both surfaces of an aluminum, stainless steel, or steel plate.

15. The insulating layer provided metal substrate of claim 13, wherein the porous aluminum oxide film has a compressive stress.

16. The insulating layer provided metal substrate of claim 14, wherein the porous aluminum oxide film has a compressive stress.

17. A semiconductor apparatus, comprising the insulating layer provided metal substrate of claim 1 and a semiconductor circuit formed on the substrate.

18. A semiconductor apparatus, comprising the insulating layer provided metal substrate of claim 7 and a semiconductor circuit formed on the substrate.

19. The semiconductor apparatus of claim 17, wherein the metal substrate is connected to a portion of the semiconductor circuit having a higher electric potential than an average electric potential of the semiconductor circuit.

20. The semiconductor apparatus of claim 18, wherein the metal substrate is connected to a portion of the semiconductor circuit having a higher electric potential than an average electric potential of the semiconductor circuit.

21. The semiconductor apparatus of claim 19, wherein the metal substrate is short-circuited to a portion of the semiconductor circuit which becomes the highest in electric potential when the semiconductor circuit is activated.

22. The semiconductor apparatus of claim 20, wherein the metal substrate is short-circuited to a portion of the semiconductor circuit which becomes the highest in electric potential when the semiconductor circuit is activated.

23. The semiconductor apparatus of claim 19, wherein the semiconductor of the semiconductor circuit is a photoelectric conversion semiconductor.

24. The semiconductor apparatus of claim 20, wherein the semiconductor of the semiconductor circuit is a photoelectric conversion semiconductor.

25. The semiconductor apparatus of claim 21, wherein the semiconductor of the semiconductor circuit is a photoelectric conversion semiconductor.

26. The semiconductor apparatus of claim 22, wherein the semiconductor of the semiconductor circuit is a photoelectric conversion semiconductor.

27. A method of manufacturing an insulating layer provided metal substrate, comprising the steps of forming the porous aluminum oxide film on a metallic aluminum provided on at least one surface of a metal substrate by anodizing the metallic aluminum, immersing the porous aluminum oxide film into a 5 mass % to 30 mass % alkali metal silicate aqueous solution or coating a 5 mass % to 30 mass % alkali metal silicate aqueous solution on the porous aluminum oxide film, and performing heat treatment on the metal substrate after the immersion or coating,
thereby forming a composite structure layer formed of the porous aluminum oxide film and an alkali metal silicate film covering the porous aluminum oxide film and pore surfaces of the porous aluminum oxide film.

28. The method of manufacturing an insulating layer provided metal substrate of claim 27, wherein the temperature of the heat treatment is 200° C. to 600° C.
